(19) United States
(12) Patent Application Publication
(10) Pub. No.: US 2023/0422609 A1
(43) Pub. Date: Dec. 28, 2023

(54) ORGANIC ELECTROLUMINESCENT DEVICE

(71) Applicant: BEIJING SUMMER SPROUT TECHNOLOGY CO., LTD., Beijing (CN)

(72) Inventors: Menglan Xie, Beijing (CN); Jing Wang, Beijing (CN); Huiqing Pang, Beijing (CN); Liang Gao, Beijing (CN); Zhihao Cui, Beijing (CN); Hualong Ding, Beijing (CN); Renjie Zheng, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/214,791

(22) Filed: Jun. 27, 2023

(30) Foreign Application Priority Data
Jun. 28, 2022 (CN) 202210737918.9

(51) Int. Cl. H10K 85/60; C09K 11/06

(52) U.S. Cl. CPC H10K 85/656; C09K 11/06; H10K 85/6574; H10K 50/12

(57) ABSTRACT

Provided is an organic electroluminescent device. The organic electroluminescent device comprises an anode, a cathode, and an organic layer disposed between the anode and the cathode, wherein the organic layer comprises a first organic layer and a second organic layer; the first organic layer comprises a first organic material and a first p-type dopant; the second organic layer comprises a second organic material and a second p-type dopant; the first organic layer is in contact with the second organic layer, and the second organic layer is above the first organic layer; and the p-type dopant has a structure represented by Formula 1. The organic electroluminescent device comprising the p-type dopant of a particular structure and having a particular device structure can significantly improve the overall performance of the device and especially improve the lifetime of the device. Further provided is an electronic assembly comprising the organic electroluminescent device.

### CROSS-REFERENCE TO RELATED APPLICATION(S)

This application claims priority to Chinese Patent Application No. 202210737918.9 filed on Jun. 28, 2022, the disclosure of which is incorporated herein by reference in its entirety.

### TECHNICAL FIELD

The present application relates to an organic electroluminescent device and, in particular, relates to an organic electroluminescent device having particular organic layers with at least two layers in contact with each other and comprising particular p-type dopants. The present application also relates to an electronic assembly comprising the organic electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes, and organic plasmon emitting devices.

An organic electroluminescent device (such as an OLED) is composed of a cathode, an anode, and a series of organic layers stacked between the cathode and the anode, converts electrical energy into light through a voltage applied at both the cathode and the anode of the device, and has the advantages of a wide angle, a high contrast, and a faster response time. In 1987, Tang and Van Slyke of Eastman Kodak reported an organic light-emitting device, which includes an arylamine hole transporting layer and a tris-8-hydroxyquinolato-aluminum layer as an electron transporting layer, and an emissive layer (Applied Physics Letters, 1987, 51 (12): 913-915). Once a voltage is applied across the device, green light was emitted from the device. This device laid a foundation for the development of modern OLEDs. Since the OLED is a self-emitting solid state device, it offers tremendous potential for display and lighting applications. In addition, the inherent properties of organic materials, such as their flexibility, may make them suited for particular applications such as the fabrication of flexible display or lighting on flexible substrates. The OLED has the advantages of a low cost, low power consumption, high brightness, a wide viewing angle, a small thickness, etc. and has been widely applied in the fields of display and lighting after decades of development.

An OLED device is generally composed of multiple organic functional layers stacked. In addition to an emissive layer (EML), the OLED device also includes a hole injection layer (HIL), a hole transporting layer (HTL), an electron blocking layer (EBL), a hole blocking layer (HBL), an electron transporting layer (ETL), an electron injection layer (EIL), and other functional layers. The hole injection layer and the electron injection layer inject holes and electrons into the device from an anode and a cathode, respectively. Then, two kinds of carriers are migrated to the emissive layer through transporting layers and recombined into excitons in the emissive layer, and radiation occurs when the excitons fall back from an excited state to a ground state, thereby achieving light emission. The electron blocking layer and the hole blocking layer are generally optional.

The effective recombination of electrons and holes is an important factor affecting the quantum efficiency of light emission of the device. At present, the carrier balance of the OLED device is mainly improved by the following three methods: the first is to use appropriate electron and hole injection materials to balance carrier concentrations, the second is to use appropriate electron and hole transporting materials to change the abilities of the transporting materials to transport carriers to achieve the balance, and the third is to adjust the transporting performance of a host material and/or a emissive material in the emissive layer to achieve the carrier balance. Hole transporting materials (HTMs) in the existing OLED device are mostly arylamine compounds which have relatively strong electron donation abilities and thus can achieve good hole conduction. Assuming that electrons and holes injected from the cathode and the anode have the same concentration, due to a difference between organic materials in performance, a hole mobility is higher than an electron mobility in the OLED structure, that is, the concentration of holes transported to the emissive layer is much greater than the concentration of electrons transported to the emissive layer, resulting in an imbalance in carrier concentration and forming a hole-rich device. A carrier imbalance easily causes carriers to accumulate at an interface between film layers and generate heat, accelerating the aging of the device and reducing a lifetime, but also the carrier imbalance reduces the recombination probability of excitons, resulting in a decrease in device efficiency. Although the carrier balance can be achieved by improving electron injection and transporting performance, relatively few types of organic materials are selectable.

To balance electrons and holes in the OLED, a traditional method is generally to increase the thickness of the hole transporting layer so that the electrons and the holes can be effectively recombined in the emissive layer within the same time without causing hole accumulation. However, the increase of the thickness of the hole transporting layer causes negative effects such as an increased voltage, reduced efficiency, and even a shortened lifetime.

Patent CN100373656C discloses an organic light-emitting display element, where a hole injection layer cooperates with a first hole transporting layer, the hole injection layer uses carbon fluoride, and the first hole transporting layer uses a p-type dopant. Hole injection is promoted through the hole injection layer, and the ability of a hole transporting layer to transport holes is promoted through the first hole transporting layer containing the p-type dopant, so as to increase a device lifetime and stabilize a device voltage. This patent reduces the voltage by introducing the p-type doped first hole transporting layer. However, the device disclosed in this patent comprises only one p-type doped organic layer, and multiple p-type doped organic layers are not disclosed.

Patent CN109216565B discloses an organic electroluminescent device whose hole injection layer is composed of a first doped layer and a second doped layer, wherein the first doped layer is composed of a p-type dopant selected from NPD-2 or NPD-9 to promote the injection of a large amount of holes; and the second doped layer includes a p-type dopant and a hole transporting material, and a doping concentration is adjusted to adjust the amount of holes injected so that the balance between electrons and holes is adjusted, thereby improving the lifetime of the device. The first doped layer in this application uses an organic layer comprising only the p-type dopant, that is, the device disclosed in this patent comprises only one p-type doped organic layer, and multiple p-type doped organic layers are not disclosed.

### SUMMARY

In view of the preceding problems, the present disclosure aims to provide a novel organic electroluminescent device. The organic electroluminescent device comprises an anode, a cathode, and an organic layer disposed between the anode and the cathode, wherein the organic layer comprises a first organic layer and a second organic layer in direct contact with each other, and the second organic layer is above the first organic layer; the first organic layer comprises a first organic material and a first p-type dopant; the second organic layer comprises a second organic material and a second p-type dopant; and the p-type dopant has a structure of Formula 1. The organic electroluminescent device comprising the p-type dopant of a particular structure and having a particular device structure can significantly improve the overall performance of the device and especially improve the lifetime of the device.

According to an embodiment of the present disclosure, an organic electroluminescent device is disclosed, which comprises an anode, a cathode, and an organic layer disposed between the anode and the cathode; wherein
the organic layer comprises a first organic layer and a second organic layer;
the first organic layer comprises a first organic material and a first p-type dopant;
the second organic layer comprises a second organic material and a second p-type dopant;
the first organic layer is in contact with the second organic layer, and the second organic layer is above the first organic layer; and
the first p-type dopant and the second p-type dopant each independently have a structure represented by Formula 1:

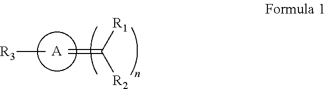

wherein
n is selected from an integer from 1 to 5;
the ring A is, at each occurrence identically or differently, selected from a conjugated ring having 4 to 30 ring atoms;
R₃ represents mono-substitution, multiple substitutions, or non-substitution;
R₁, R₂, and R₃ are, at each occurrence identically or differently, selected from hydrogen, deuterium, or a substituent;
at least one R₃ is selected from hydrogen, deuterium, or a substituent comprising at least two atoms; and
adjacent substituents R₁, R₂, R₃ can be optionally joined to form a ring.

According to an embodiment of the present disclosure, an electronic assembly is further disclosed, which comprises the organic electroluminescent device in the preceding embodiment.

The present disclosure provides a novel organic electroluminescent device. The organic electroluminescent device comprises an anode, a cathode, and an organic layer disposed between the anode and the cathode, wherein the organic layer comprises a first organic layer and a second organic layer in direct contact with each other, and the second organic layer is above the first organic layer; the first organic layer comprises a first organic material and a first p-type dopant; the second organic layer comprises a second organic material and a second p-type dopant; and the p-type dopant has a structure of Formula 1. The organic electroluminescent device comprising the p-type dopant of a particular structure and having a particular device structure can significantly improve the overall performance of the device and especially improve the lifetime of the device.

### BRIEF DESCRIPTION OF DRAWINGS

FIG. 1 is a schematic diagram of an organic light-emitting device 100.

FIG. 2 is a schematic diagram of an organic light-emitting device 200.

FIG. 3 is a schematic diagram of an organic electroluminescent device 300.

FIG. 4 is a schematic diagram of an organic electroluminescent device 400 with stacked layers.

### DETAILED DESCRIPTION

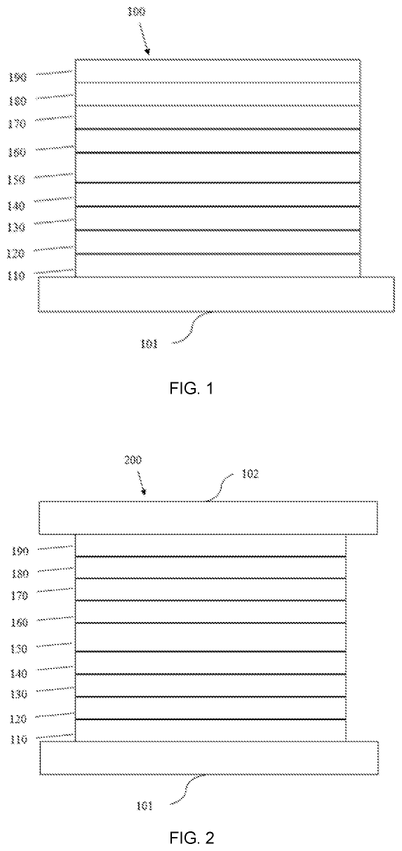

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. The device 100 may include a substrate 101, an anode 110, a hole injection layer 120, a hole transporting layer 130, an electron blocking layer 140 (optional), an emissive layer 150, a hole blocking layer 160 (optional), an electron transporting layer 170, an electron injection layer 180, and a cathode 190. The device 100 may be fabricated by depositing the layers described in order. In some applications, the hole injection layer 120 and the hole transporting layer 130 are collectively referred to as the hole transporting layer or referred to as a first hole transporting layer and a second hole transporting layer. However, the hole injection layer and the hole transporting layer have a relatively large difference: generally, the hole injection layer is in direct contact with the anode and is generally thinner than the hole transporting layer. The properties and functions of the layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-type doped hole transporting layer is m-MTDATA doped with F₄-TCNQ at a molar ratio of 1:50, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transporting layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. For example, the hole blocking layer is not a necessary layer and can be omitted in some structures. It may also include other layers not specifically described. Within each layer, a single material or a mixture of multiple materials can be used to achieve optimum performance. Any functional layer may include several sublayers. For example, the emissive layer may have two layers of different emissive materials to achieve desired emission spectrum.

In one embodiment, an OLED may be described as having an “organic layer” disposed between a cathode and an anode. The organic layer may comprise a single layer or multiple layers.

An OLED can be encapsulated by a bather layer. FIG. 2 schematically shows an organic light-emitting device 200 without limitation. FIG. 2 differs from FIG. 1 in that the organic light-emitting device include a barrier layer 102, which is above the cathode 190, to protect it from harmful species from the environment, such as moisture and oxygen. Any material that can provide the barrier function can be used as the barrier layer, such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3D displays, vehicles displays, and vehicle tail lights.

The materials and structures described herein may be used in other organic electronic devices listed above.

There are various methods for OLED fabrication. Small molecule OLEDs are generally fabricated by vacuum thermal evaporation. Polymer OLEDs are fabricated by solution process such as spin coating, inkjet printing, and slit printing. If the material can be dissolved or dispersed in a solvent, the small molecule OLED can also be produced by solution process. Organic layers in the organic electroluminescent device provided by the present application can be prepared by evaporation or solution process. For example, a first organic layer and a second organic layer in the present application can be prepared by evaporation or solution process as required.

Herein, energy levels of a compound (a lowest unoccupied molecular orbital (LUMO) energy level and a highest occupied molecular orbital (HOMO) energy level) are measured by a cyclic voltammetry method. For example, the LUMO energy level of the compound HATCN

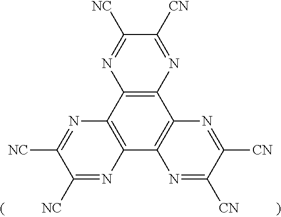 [SMILES: N#Cc1nc2c3nc(C#N)c(C#N)nc3c3nc(C#N)c(C#N)nc3c2nc1C#N]

measured by the test method of the present application is −4.33 eV. Herein, all “LUMO energy levels” and “HOMO energy levels” are expressed as negative values, and the smaller the numerical value (i.e., the larger the absolute value), the deeper the energy level. Herein, the expression that the energy level is smaller than a certain number means that the numerical value of the energy level is smaller than this number, i.e., is more negative. For example, the LUMO energy level of a certain organic material is ≤−4.2 eV, which means that the numerical value of the LUMO energy level of the organic material is equal to −4.2 eV or more negative than −4.2 eV, that is, the LUMO energy level of the organic material is deeper than 4.2 eV.

The term “doping proportion” refers to the percentage of a material in an organic layer to the total mass of the organic layer. For example, the doping proportion of a first p-type dopant in a first organic layer, which is mentioned in the present application, refers to the percentage of the first p-type dopant to the total mass of the first organic layer; when the first organic layer is composed of a first organic material and the first p-type dopant, the total mass of the first organic layer is the sum of the mass of the first organic material and the mass of the first p-type dopant.

In the present application, the term “the same as” or “different from” is used in the context of a material, for example, that “a first p-type dopant is different from a second p-type dopant” or that “a first organic material is the same as or different from a second organic material”. The term “the same as” therein refers to that two or more materials have the same chemical structural formula, or two or more materials differ only in that hydrogens in the chemical structural formula are partially or fully substituted with deuterium. Conversely, the term “different from” therein refers to that the organic materials used have different chemical structural formulas (that is, the chemical structural formulas differ not only in that hydrogens in the molecular formula are partially or fully substituted with deuterium).

In the present application, the expression that organic layers are “different” means that: if each organic layer comprises a single material, it means that the organic layers comprise different materials; if each organic layer is a composite material/layer comprising at least two materials, it means that at least one of the materials comprised in the organic layer is different or the composite materials/layers formed in the organic layers are different (the composite materials/layers comprise different materials and/or have different doping proportions). The expression that organic layers are “the same” means that the organic layers comprise the same materials and have the same doping proportion.

As used herein, the “p-type dopant” refers to a dopant with an oxidation ability, which has a strong electron withdrawing ability and is an electron acceptor. The “p-type dopant” refers to a molecular p-type dopant herein.

As used herein, the “molecular p-type dopant” refers to an organic compound composed of more than 6 atoms in a dopant molecule. Preferably, the number of atoms forming the dopant molecule is greater than 10. More preferably, the number of atoms forming the dopant molecule is greater than 20. Preferably, the molar mass of the “molecular p-type organic dopant” is between 200 g/mol and 2000 g/mol, preferably between 300 g/mol and 1800 g/mol, more preferably between 400 g/mol and 1500 g/mol.

As used herein, “top” means furthest away from the anode, while “bottom” means closest to the anode. Where a second layer is described as “disposed above” a first layer, the first layer is closer to the anode. Conversely, where the second layer is described as “disposed below” the first layer, the second layer is closer to the anode. There may be other layers between the first layer and the second layer, unless it is specified that the first layer is “in contact with” the second layer. For example, a cathode may be described as “disposed above” the anode even though there are various organic layers therebetween.

As used herein, the “emissive unit” refers to an organic material layer that emits light by applying a voltage or current. The “emissive unit” includes at least an emissive layer, and the emissive layer may further include a host material and a emissive material. The “emissive unit” further includes at least a pair of hole and electron injection/transporting layers, for example, a hole injection layer, a hole transporting layer, an electron blocking layer, a hole blocking layer, an electron transporting layer, and an electron injection layer.

As used herein, the “charge generation layer (CGL)” is a layer disposed between two emissive units to provide electrons and holes and is composed of an n-type charge generation layer and a p-type charge generation layer. The n-type charge generation layer is in contact with the electron transporting layer or electron injection layer of one emissive unit, and the p-type charge generation layer is generally in contact with the hole injection layer or hole transporting layer of an adjacent emissive unit and provides holes for the adjacent emissive unit. The p-type charge generation layer may be a p-type dopant of a single material or a composite layer of a hole transporting material doped with a p-type dopant.

Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthyl isopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyl diethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzonlquinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

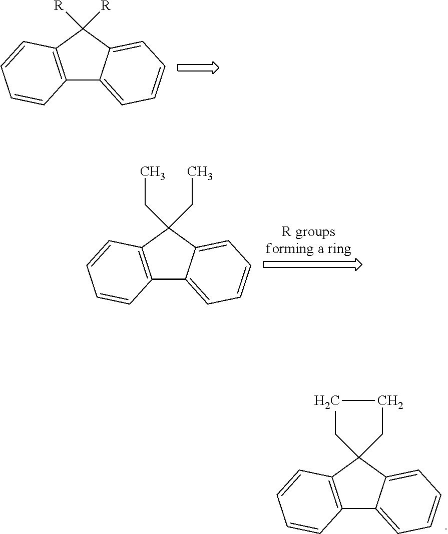

The expression that adjacent substituents can be optionally joined to form a ring is also intended to mean that two substituents bonded to carbon atoms which are directly bonded to each other are joined to each other via a chemical bond to form a ring, which can be exemplified by the following formula:

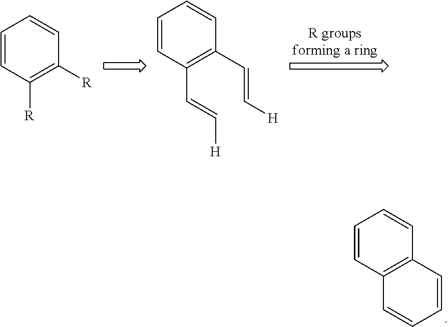

The expression that adjacent substituents can be optionally joined to form a ring is also intended to mean that two substituents bonded to a further distant carbon atom are joined to each other via a chemical bond to form a ring, which can be exemplified by the following formula:

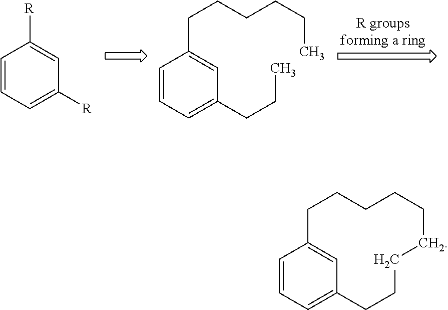

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

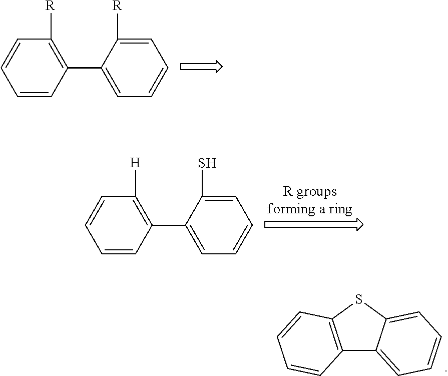

According to an embodiment of the present disclosure, an organic electroluminescent device is disclosed, which comprises an anode, a cathode, and an organic layer disposed between the anode and the cathode; wherein
the organic layer comprises a first organic layer and a second organic layer;
the first organic layer comprises a first organic material and a first p-type dopant;
the second organic layer comprises a second organic material and a second p-type dopant;
the first organic layer is in contact with the second organic layer, and the second organic layer is above the first organic layer; and
the first p-type dopant and the second p-type dopant each independently have a structure represented by Formula 1:

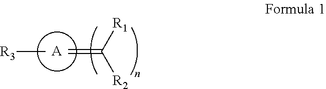

wherein
n is selected from an integer from 1 to 5;
the ring A is, at each occurrence identically or differently, selected from a conjugated ring having 4 to 30 ring atoms;
R₃ represents mono-substitution, multiple substitutions, or non-substitution;
R₁, R₂, and R₃ are, at each occurrence identically or differently, selected from hydrogen, deuterium, or a substituent;
at least one R₃ is selected from hydrogen, deuterium, or a substituent comprising at least two atoms; and
adjacent substituents R₁, R₂, R₃ can be optionally joined to form a ring.

Herein, the expression that “the ring A is a conjugated ring having 4 to 30 ring atoms” is intended to mean that the ring A is a ring structure having 4 to 30 ring atoms and the ring A has a structural feature of being conjugated. For example, the ring A includes, but is not limited to, the structures shown by Formula 2 to Formula 13 in the present application. The ring A may be a monocyclic structure or a polycyclic structure, wherein the polycyclic ring may be a parallel-ring structure or a fused-ring structure or may be an integrally conjugated structure formed by connecting two conjugated rings by a double bond, such as the structure shown by Formula 13 in the present application. The ring A may be a carbocyclic ring or a heterocyclic ring.

Herein, the expression that “adjacent substituents R₁, R₂, R₃ can be optionally joined to form a ring” is intended to mean that any one or more of groups of adjacent substituents, such as substituents R₃, substituents R₁ and R₂, substituents R₁ and R₃, and substituents R₂ and R₃, can be joined to form a ring. Obviously, it is also possible that none of these substituents are joined to form a ring.

According to an embodiment of the present disclosure, n is selected from 1, 2, or 3.

According to an embodiment of the present disclosure, n is selected from 1 or 2.

According to an embodiment of the present disclosure, the ring A is, at each occurrence identically or differently, selected from a conjugated ring having 4 to 20 ring atoms.

According to an embodiment of the present disclosure, the ring A is, at each occurrence identically or differently, selected from a conjugated ring having 4 to 15 ring atoms.

According to an embodiment of the present disclosure, the ring A is, at each occurrence identically or differently, selected from the group consisting of Formula 2 to Formula 13:

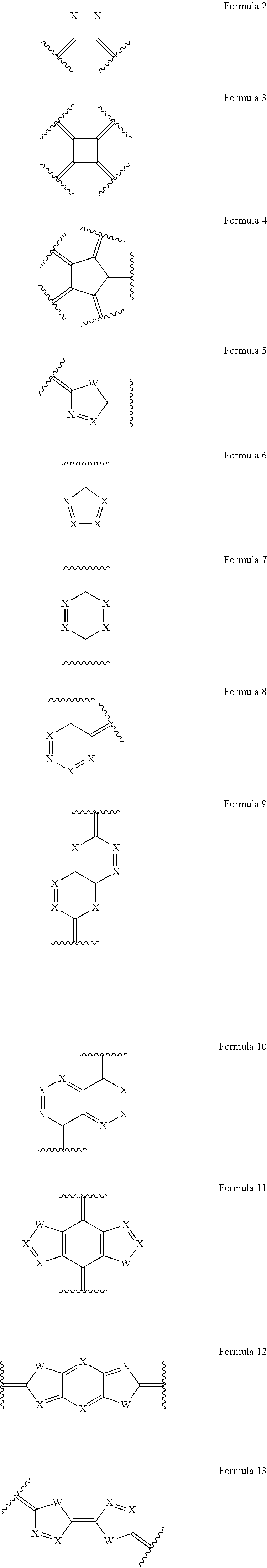

wherein
X is, at each occurrence identically or differently, selected from the group consisting of N and CR₃;
W is, at each occurrence identically or differently, selected from the group consisting of O, S, Se, and NR₃;
at least one R₃ is selected from hydrogen, deuterium, or a substituent comprising at least two atoms;
adjacent substituents R₁, R₂, R₃ can be optionally joined to form a ring; and
“ [symbol] ” represents a position where Formula 2 to Formula 13 are joined to a double bond in Formula 1.

According to an embodiment of the present disclosure, the p-type dopant has a structure represented by any one of Formula 14 to Formula 17:

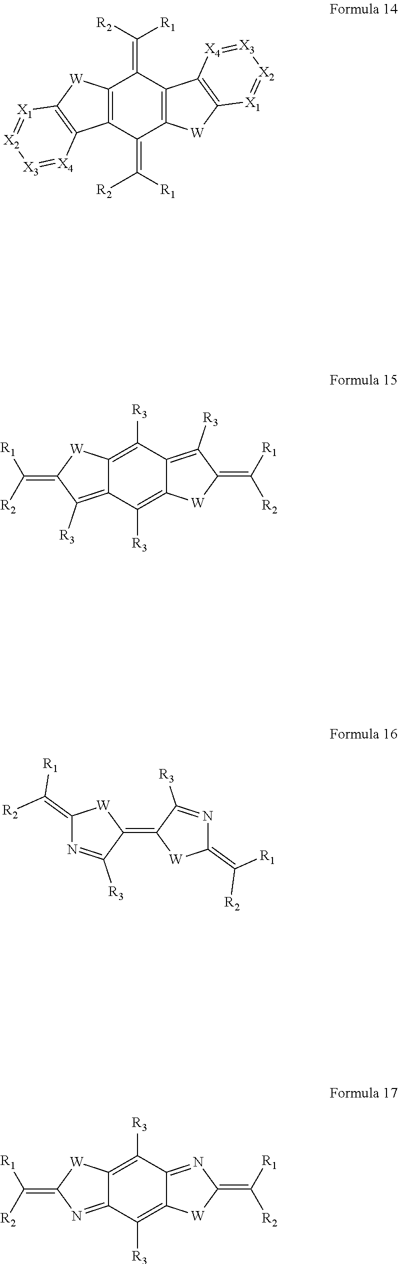

wherein
X₁, X₂, X₃, and X₄ are, at each occurrence identically or differently, selected from the group consisting of N and CR₃;
W is, at each occurrence identically or differently, selected from the group consisting of O, S, Se, and NR₃;
R₁, R₂, and R₃ are, at each occurrence identically or differently, selected from hydrogen, deuterium, or a substituent;
at least one R₃ is selected from hydrogen, deuterium, or a substituent comprising at least two atoms; and
adjacent substituents R₁, R₂, R₃ can be optionally joined to form a ring.

According to an embodiment of the present disclosure, W is, at each occurrence identically or differently, selected from O, S, or Se.

According to an embodiment of the present disclosure, W is, at each occurrence identically or differently, selected from O or S.

According to an embodiment of the present disclosure, W is selected from O.

According to an embodiment of the present disclosure, W is, at each occurrence identically or differently, selected from NR₃, and R₃ is, at each occurrence identically or differently, selected from the group consisting of: substituted or unsubstituted alkyl having 1 to carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, W is, at each occurrence identically or differently, selected from NR₃, and R₃ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, the substituent is selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least one R₃ is selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof.

According to an embodiment of the present disclosure, a sum of the thickness of the first organic layer and the thickness of the second organic layer is less than or equal to 100 nm.

According to an embodiment of the present disclosure, the sum of the thickness of the first organic layer and the thickness of the second organic layer is less than or equal to 50 nm.

According to an embodiment of the present disclosure, the sum of the thickness of the first organic layer and the thickness of the second organic layer is less than or equal to 30 nm.

According to an embodiment of the present disclosure, the sum of the thickness of the first organic layer and the thickness of the second organic layer is less than or equal to 20 nm.

According to an embodiment of the present disclosure, the sum of the thickness of the first organic layer and the thickness of the second organic layer is greater than or equal to 5 nm.

According to an embodiment of the present disclosure, the sum of the thickness of the first organic layer and the thickness of the second organic layer is greater than or equal to 10 nm.

According to an embodiment of the present disclosure, the first organic material is the same as the second organic material.

According to an embodiment of the present disclosure, the first organic material is different from the second organic material.

According to an embodiment of the present disclosure, the first p-type dopant is the same as the second p-type dopant.

According to an embodiment of the present disclosure, the first p-type dopant is different from the second p-type dopant.

According to an embodiment of the present disclosure, a doping proportion of the first p-type dopant in the first organic layer is less than a doping proportion of the second p-type dopant in the second organic layer.

When a low concentration of p-type dopant is used in the first organic layer (i.e., the lower layer close to the anode), the number of injected holes can be controlled, and when a high concentration of p-type dopant is used in the second organic layer (i.e., the upper layer close to the cathode), the number of injected holes can be balanced.

According to an embodiment of the present disclosure, the doping proportion of the first p-type dopant in the first organic layer is greater than or equal to the doping proportion of the second p-type dopant in the second organic layer.

According to an embodiment of the present disclosure, the first p-type dopant has a LUMO of greater than or equal to −5.2 eV.

According to an embodiment of the present disclosure, the first p-type dopant has a LUMO of greater than or equal to −5.0 eV.

According to an embodiment of the present disclosure, the first p-type dopant has a LUMO of greater than or equal to −4.9 eV.

According to an embodiment of the present disclosure, the second p-type dopant has a LUMO of greater than or equal to −5.2 eV.

According to an embodiment of the present disclosure, the second p-type dopant has a LUMO of greater than or equal to −5.0 eV.

According to an embodiment of the present disclosure, the second p-type dopant has a LUMO of greater than or equal to −4.9 eV.

According to an embodiment of the present disclosure, the first p-type dopant and/or the second p-type dopant have a LUMO of less than or equal to −4.2 eV.

According to an embodiment of the present disclosure, the first p-type dopant and/or the second p-type dopant have a LUMO of less than or equal to −4.3 eV.

According to an embodiment of the present disclosure, the first p-type dopant and/or the second p-type dopant have a LUMO of less than or equal to −4.5 eV.

According to an embodiment of the present disclosure, the LUMO of the first p-type dopant is less than or equal to the LUMO of the second p-type dopant.

According to an embodiment of the present disclosure, the LUMO of the first p-type dopant is greater than the LUMO of the second p-type dopant.

According to an embodiment of the present disclosure, the first organic material and/or the second organic material have a HOMO energy level of less than or equal to −4.5 eV.

According to an embodiment of the present disclosure, the first organic material and/or the second organic material have a HOMO energy level of less than or equal to −4.8 eV.

According to an embodiment of the present disclosure, the first organic material and/or the second organic material are selected from the group consisting of the following compounds: a compound having a triarylamine unit, a spirobifluorene compound, a pentacene compound, an oligothiophene compound, an oligophenyl compound, an oligophenylenevinylene compound, an oligofluorene compound, a porphyrin complex, and a metallic phthalocyanine complex.

According to an embodiment of the present disclosure, the doping proportion of the first p-type dopant in the first organic layer is greater than or equal to 0.01% and less than or equal to 99.9%.

According to an embodiment of the present disclosure, the doping proportion of the first p-type dopant in the first organic layer is greater than or equal to 0.1% and less than or equal to 99.9%.

According to an embodiment of the present disclosure, the doping proportion of the first p-type dopant in the first organic layer is greater than or equal to 0.5% and less than or equal to 50%.

According to an embodiment of the present disclosure, the doping proportion of the second p-type dopant in the second organic layer is greater than or equal to 0.01% and less than or equal to 99.9%.

According to an embodiment of the present disclosure, the doping proportion of the second p-type dopant in the second organic layer is greater than or equal to 0.1% and less than or equal to 99.9%.

According to an embodiment of the present disclosure, the doping proportion of the second p-type dopant in the second organic layer is greater than or equal to 0.5% and less than or equal to 50%.

According to an embodiment of the present disclosure, a third organic layer is further comprised above the second organic layer, wherein the third organic layer comprises a third organic material and a third p-type dopant.

According to an embodiment of the present disclosure, the third organic material is the same as or different from the first organic material and/or the second organic material.

According to an embodiment of the present disclosure, the third p-type dopant is the same as or different from the first p-type dopant and/or the second p-type dopant.

According to an embodiment of the present disclosure, the third organic material is defined the same as the first organic material and/or the second organic material.

According to an embodiment of the present disclosure, the third p-type dopant is defined the same as the first p-type dopant and/or the second p-type dopant.

According to an embodiment of the present disclosure, the organic electroluminescent device may have more than two organic layers comprising a p-type dopant, for example, three, four, or five organic layers comprising a p-type dopant. When the organic electroluminescent device has more than two organic layers comprising a p-type dopant, for example, when a third organic layer is further comprised above the second organic layer, the third organic layer comprises a third organic material and a third p-type dopant. The doping proportions of the p-type dopants in the more than two organic layers may increase at a gradient along the direction from the anode to the cathode, or may decrease at a gradient along the direction from the anode to the cathode, or may change as a parabolic curve (i.e. the doping proportion increases first and then decreases or the doping proportion decreases first and then increases). Of course, the doping proportions may be consistent as required.

According to an embodiment of the present disclosure, the first organic material, the second organic material, and the third organic material are all hole transporting materials.

According to an embodiment of the present disclosure, R₁ and/or R₂ are a substituent comprising at least one electron withdrawing group.

According to an embodiment of the present disclosure, a Hammett constant of the electron withdrawing group is ≥0.05, preferably ≥0.3, more preferably ≥0.5.

In the present disclosure, the Hammett substituent constant value of the electron withdrawing group is ≥0.05, for example, ≥0.1 or ≥0.2; preferably ≥0.3; more preferably ≥0.5. The electron withdrawing ability is relatively strong, which can significantly reduce the LUMO energy level of the compound and achieve the improvement of a charge mobility.

It is to be noted that the Hammett substituent constant value includes a para constant and/or a meta constant of a Hammett substituent, and as long as the para constant and the meta constant are greater than 0 and one of the para constant and the meta constant is greater than or equal to 0.05, the Hammett substituent can be used as the group selected in the present disclosure.

According to an embodiment of the present disclosure, the electron withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boranyl group, a sulfonyl group, a sulfonyl group, a phosphoroso group, an aza-aromatic ring group, and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, and an aza-aromatic ring group: alkyl having 1 to 20 carbon atoms, cycloalkyl having 3 to 20 ring carbon atoms, heteroalkyl having 1 to 20 carbon atoms, a heterocyclic group having 3 to 20 ring atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof.

According to an embodiment of the present disclosure, the electron withdrawing group is selected from the group consisting of: halogen, a nitroso group, a nitro group, an acyl group, a carbonyl group, a carboxylic acid group, an ester group, SF₅, a boranyl group, a sulfinyl group, a sulfonyl group, a phosphoroso group, an aza-aromatic ring group, and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof.

According to an embodiment of the present disclosure, the electron withdrawing group is selected from the group consisting of: fluorine, an acyl group, a carbonyl group, an ester group, SF₅, a boranyl group, an aza-aromatic ring group, and any one of the following groups substituted with one or more of fluorine, a cyano group, an isocyano group, SCN, OCN, SF₅, CF₃, OCF₃, SCF₃, and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof.

According to an embodiment of the present disclosure, the p-type dopant is selected from the group consisting of the following structures which are included without limitation:

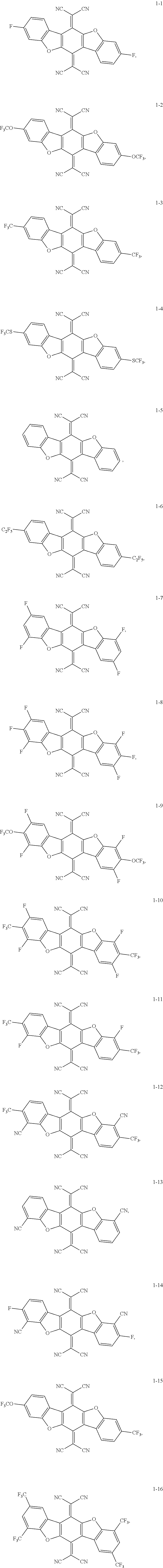

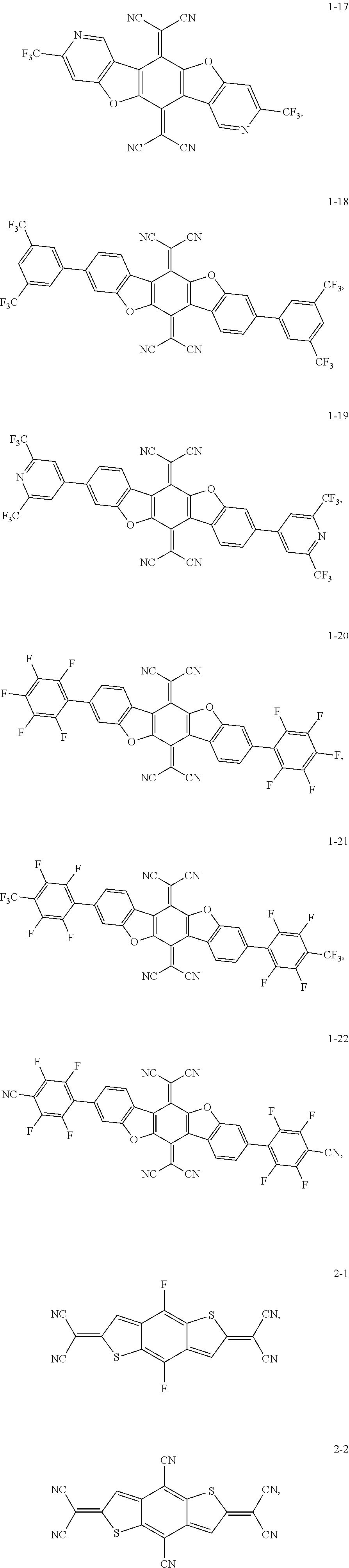

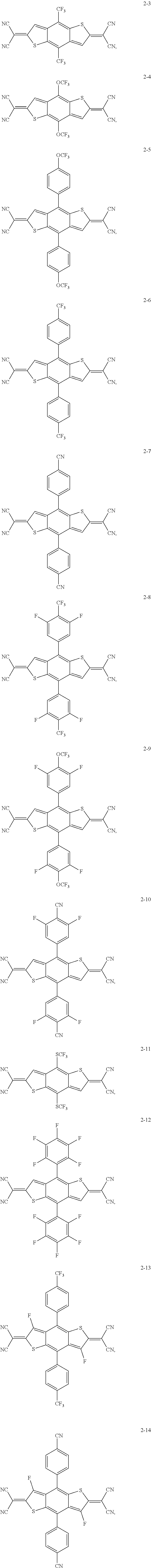

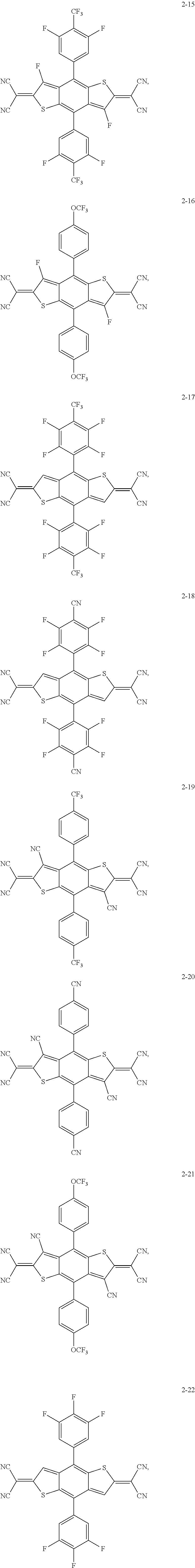

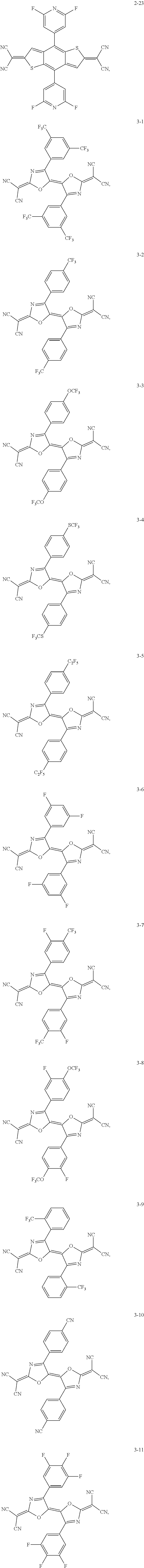

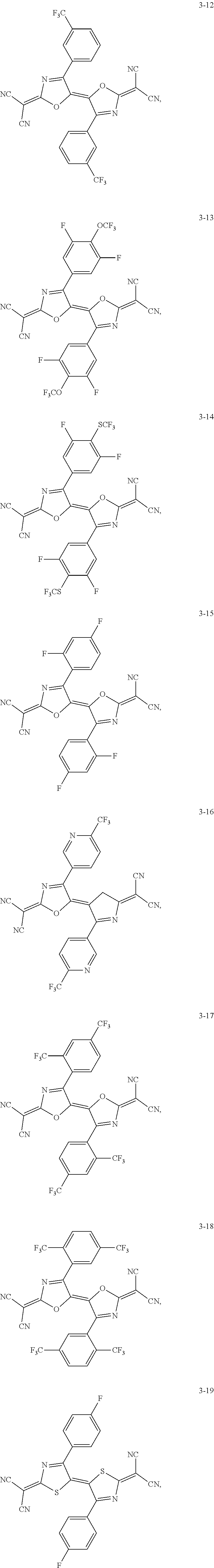

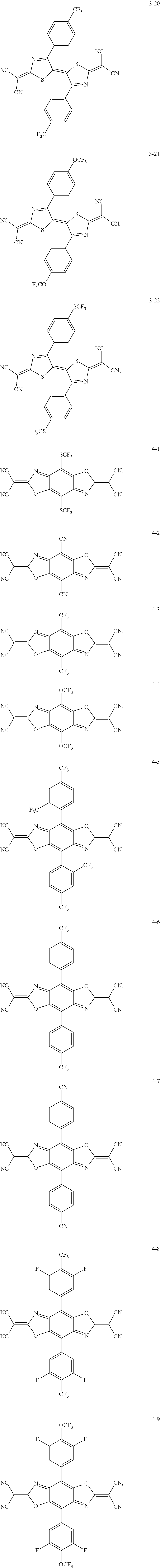

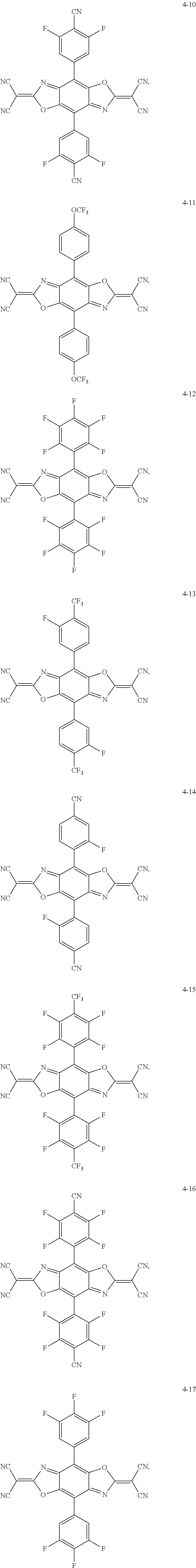

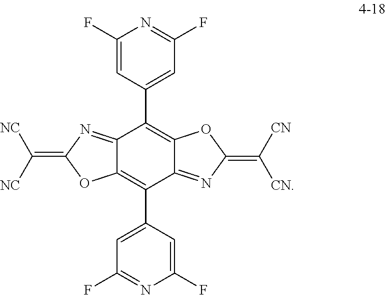 [SMILES: N#CC(C#N)=c1nc2c(-c3cc(F)nc(F)c3)c3oc(=C(C#N)C#N)nc3c(-c3cc(F)nc(F)c3)c2o1]

According to an embodiment of the present disclosure, the first organic layer is in contact with the anode.

According to an embodiment of the present disclosure, the organic electroluminescent device further comprises at least one emissive layer disposed between the second organic layer and the cathode.

According to an embodiment of the present disclosure, the emissive layer comprises a emissive material, wherein the emissive material is a phosphorescent, fluorescent, or delayed fluorescence material.

According to an embodiment of the present disclosure, the organic electroluminescent device further comprises a fourth organic layer disposed between the second organic layer and the emissive layer, wherein the fourth organic layer comprises the first organic material or the second organic material.

According to an embodiment of the present disclosure, the organic electroluminescent device further comprises a charge generation layer disposed between the emissive layer and the cathode, wherein the charge generation layer comprises a p-type charge generation layer.

According to an embodiment of the present disclosure, the p-type charge generation layer of the charge generation layer comprises the first p-type dopant or the second p-type dopant.

According to an embodiment of the present disclosure, a doping proportion of the first p-type dopant or the second p-type dopant in the p-type charge generation layer of the charge generation layer is greater than or equal to 0.01% and less than or equal to 100%.

According to an embodiment of the present disclosure, the p-type charge generation layer of the charge generation layer comprises the p-type dopant.

According to an embodiment of the present disclosure, the p-type charge generation layer of the charge generation layer may be the first organic layer.

According to an embodiment of the present disclosure, the first organic layer or the second organic layer is in contact with the p-type charge generation layer of the charge generation layer.

According to an embodiment of the present disclosure, the organic electroluminescent device has the following single-layer device structure: anode/first organic layer/second organic layer/hole transporting layer/electron blocking layer/emissive layer/hole blocking layer/electron transporting layer/electron injection layer/cathode; wherein the electron blocking layer and the hole blocking layer are optional layers and can be selected as required. The structure of the layers as described not limited to a single-layer structure, for example, the emissive layer may be a two-layer structure, that is, the emissive layer includes two emissive layers. The third organic layer in the present disclosure may be further comprised between the second organic layer and the hole transporting layer.

According to an embodiment of the present disclosure, the organic electroluminescent device has the following stacked device structure: anode/first emissive unit/charge generation layer/second emissive unit/cathode. The first emissive unit and the second emissive unit may be the same or different and each independently have the organic layer structure between the anode and the cathode in the single-layer device structure described above. A first charge generation layer and a third emissive unit may be further comprised between the second emissive unit and the cathode, that is, the device structure is as follows: anode/first emissive unit/charge generation layer/second emissive unit/first charge generation layer/third emissive unit/cathode, wherein the third emissive unit may be the same as or different from the first emissive unit, and the third emissive unit may also be the same as or different from the second emissive unit.

According to an embodiment of the present disclosure, the first organic material and/or the second organic material comprise any one or more chemical structural units selected from the group consisting of triarylamine, carbazole, fluorene, spirobifluorene, thiophene, furan, phenyl, oligophenylenevinylene, oligofluorene, and combinations thereof.

According to an embodiment of the present disclosure, the first organic material and/or the second organic material comprise a monotriarylamine structural unit or a bistriarylamine structural unit.

According to an embodiment of the present disclosure, the first organic material and/or the second organic material comprise any one or more chemical structural units selected from the group consisting of: a monotriarylamine-carbazole structural unit, a monotriarylamine-thiophene structural unit, a monotriarylamine-furan structural unit, a monotriarylamine-fluorene structural unit, a bistriarylamine-carbazole structural unit, a bistriarylamine-thiophene structural unit, a bistriarylamine-furan structural unit, and a bistriarylamine-fluorene structural unit.

According to an embodiment of the present disclosure, the first organic material and/or the second organic material are a monotriarylamine compound or a bistriarylamine compound.

According to an embodiment of the present disclosure, the first organic material and/or the second organic material are selected from a monotriarylamine-carbazole compound, a monotriarylamine-thiophene compound, a monotriarylamine-furan compound, a monotriarylamine-fluorene compound, a bistriarylamine-carbazole compound, a bistriarylamine-thiophene compound, a bistriarylamine-furan compound, or a bistriarylamine-fluorene compound.

According to an embodiment of the present disclosure, the first organic material and/or the second organic material comprising a monotriarylamine structural unit have a structure represented by Formula 18 or Formula 19:

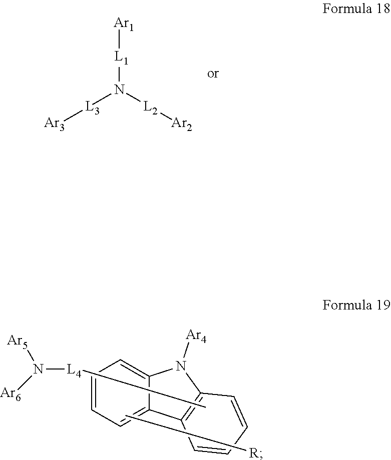

wherein Ar₁, Ar₂, Ar₃, Ar₄, Ar₅, and Ar₆ are, at each occurrence identically or differently, selected from substituted or unsubstituted aryl having 6 to 30 carbon atoms or substituted or unsubstituted heteroaryl having 3 to 30 carbon atoms; and the structures of Ar₁, Ar₂, Ar₃, Ar₄, Ar₅, and Ar₆ do not comprise carbazole;
L₁, L₂, L₃, and L₄ are, at each occurrence identically or differently, selected from a single bond, substituted or unsubstituted arylene having 6 to 30 carbon atoms, substituted or unsubstituted heteroarylene having 3 to 30 carbon atoms, or a combination thereof; and the structures of L₁, L₂, L₃, and L₄ do not comprise carbazole;
R represents, at each occurrence identically or differently, mono-substitution, multiple substitutions, or non-substitution;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof; and adjacent substituents can be optionally joined to form a ring.

According to an embodiment of the present disclosure, Ar₁, Ar₂, Ar₃, Ar₄, Ar₅, and Ar₆ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted dibenzofuryl, substituted or unsubstituted dibenzothienyl, substituted or unsubstituted dibenzoselenophenyl, substituted or unsubstituted phenanthryl, substituted or unsubstituted triphenylenyl, substituted or unsubstituted pyridyl, substituted or unsubstituted anthryl, substituted or unsubstituted pyrenyl, substituted or unsubstituted fluorenyl, or a combination thereof.

According to an embodiment of the present disclosure, L₁, L₂, L₃, and L₄ are, at each occurrence identically or differently, selected from a single bond, substituted or unsubstituted phenylene, substituted or unsubstituted biphenylene, substituted or unsubstituted terphenylene, substituted or unsubstituted naphthylene, substituted or unsubstituted dibenzofurylene, substituted or unsubstituted dibenzothienylene, substituted or unsubstituted dibenzoselenophenylene, substituted or unsubstituted phenanthrylene, substituted or unsubstituted triphenylenylene, substituted or unsubstituted pyridylene, substituted or unsubstituted anthrylene, substituted or unsubstituted pyrenylene, substituted or unsubstituted fluorenylene, or a combination thereof.

According to an embodiment of the present disclosure, the first organic material and/or the second organic material comprising a bistriarylamine structural unit have a structure represented by Formula 20:

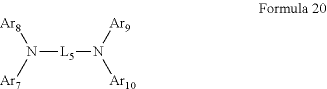

wherein Ar₇, Ar₈, Ar₉, and Ar₁₀ are selected from substituted or unsubstituted aryl having 6 to 30 carbon atoms or substituted or unsubstituted heteroaryl having 3 to 30 carbon atoms;
L₅ is selected from substituted or unsubstituted arylene having 6 to 30 carbon atoms or substituted or unsubstituted heteroarylene having 3 to 30 carbon atoms; and adjacent substituents can be optionally joined to form a ring.

According to an embodiment of the present disclosure, Ar₇, Ar₈, Ar₉, and Ar₁₀ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted carbazolyl, substituted or unsubstituted dibenzofuryl, substituted or unsubstituted dibenzothienyl, substituted or unsubstituted dibenzoselenophenyl, substituted or unsubstituted phenanthryl, substituted or unsubstituted triphenylenyl, substituted or unsubstituted pyridyl, substituted or unsubstituted anthryl, substituted or unsubstituted pyrenyl, substituted or unsubstituted fluorenyl, or a combination thereof.

According to an embodiment of the present disclosure, L₅ is selected from a single bond, substituted or unsubstituted phenylene, substituted or unsubstituted biphenylene, substituted or unsubstituted terphenylene, substituted or unsubstituted naphthylene, substituted or unsubstituted carbazolylene, substituted or unsubstituted dibenzofurylene, substituted or unsubstituted dibenzothienylene, substituted or unsubstituted dibenzoselenophenylene, substituted or unsubstituted phenanthrylene, substituted or unsubstituted triphenylenylene, substituted or unsubstituted pyridylene, substituted or unsubstituted anthrylene, substituted or unsubstituted pyrenylene, substituted or unsubstituted fluorenylene, or a combination thereof.

According to an embodiment of the present disclosure, the first organic material and/or the second organic material are selected from the group consisting of the following structures which are included without limitation:

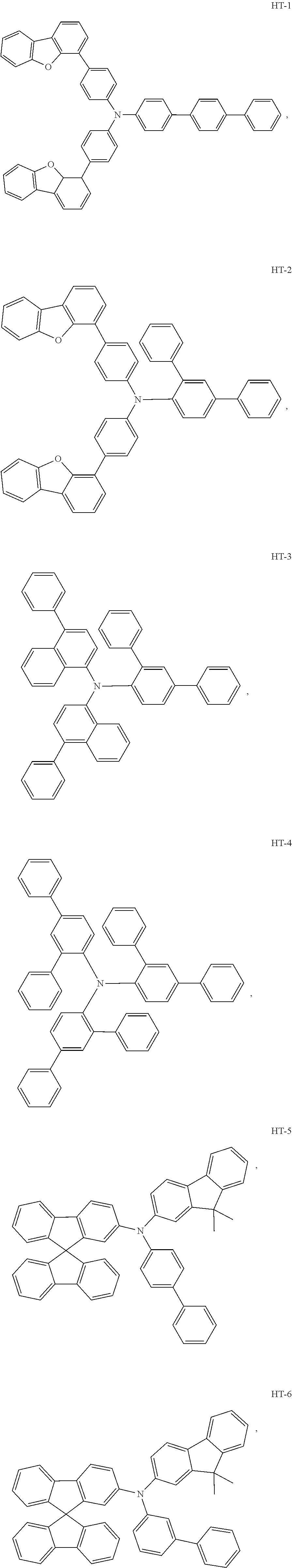

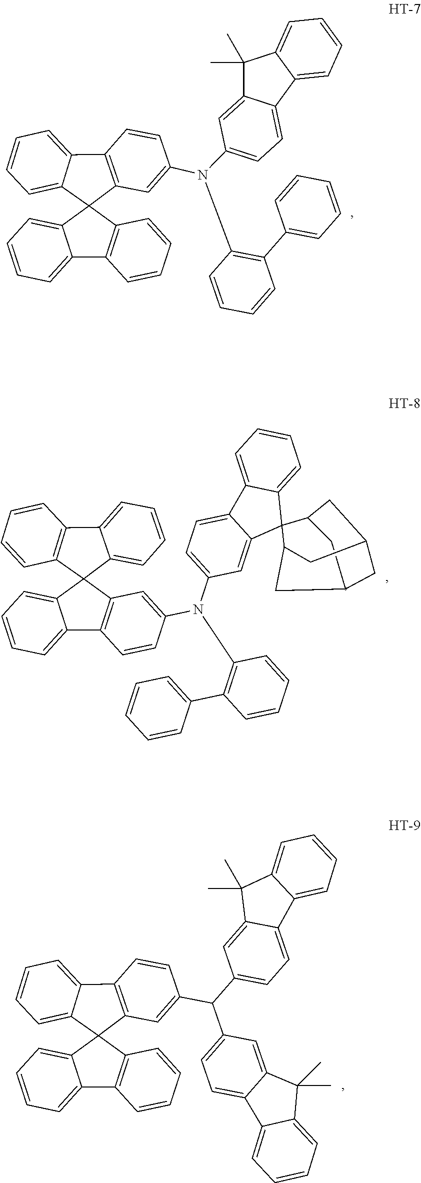

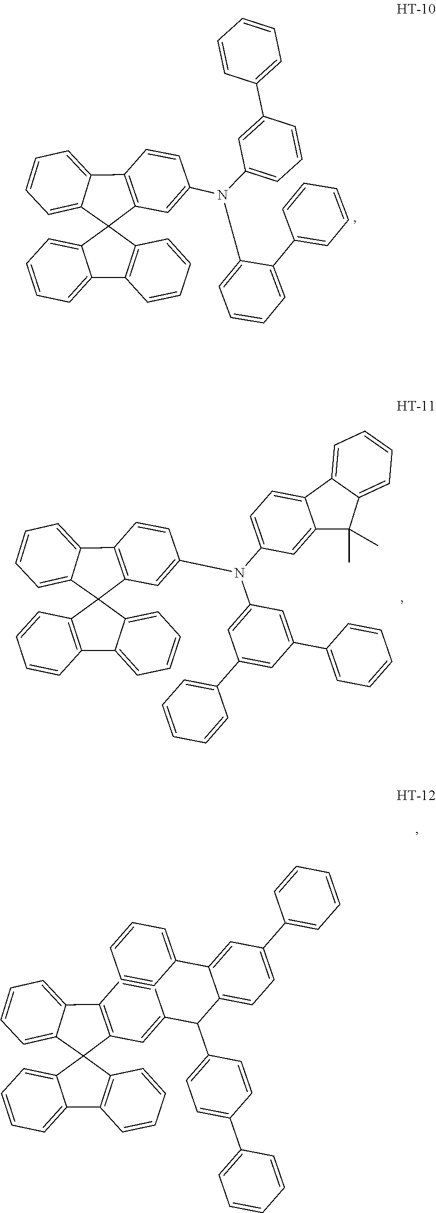

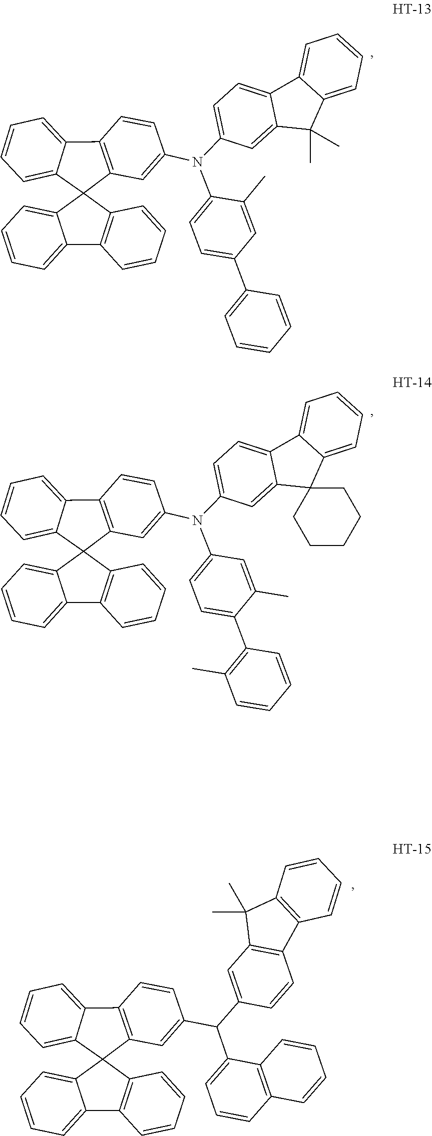

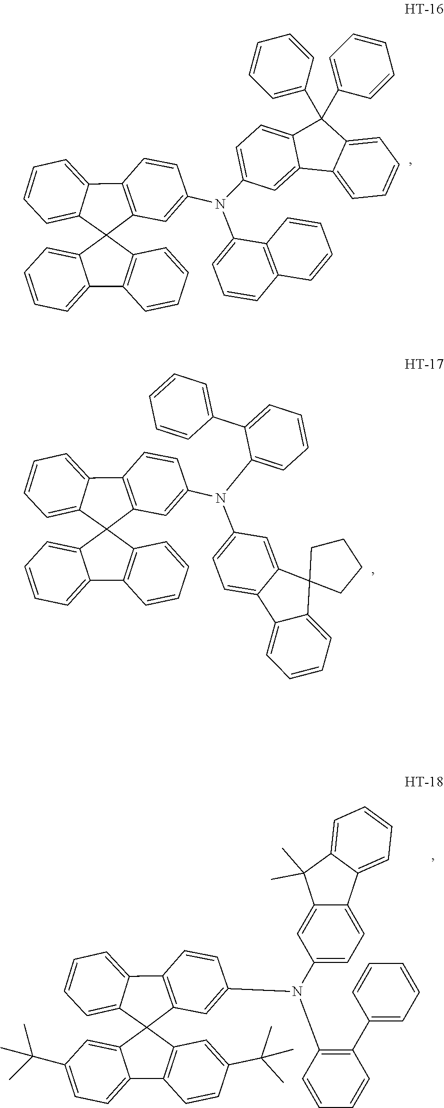 [SMILES: c1ccc(C2(c3ccccc3)c3ccccc3-c3cc(N(c4ccc5c(c4)C4(c6ccccc6-c6ccccc64)c4ccccc4-5)c4cccc5ccccc45)ccc32)cc1 ; c1ccc(-c2ccccc2N(c2ccc3c(c2)C2(CCCC2)c2ccccc2-3)c2ccc3c(c2)C2(c4ccccc4-c4ccccc42)c2ccccc2-3)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

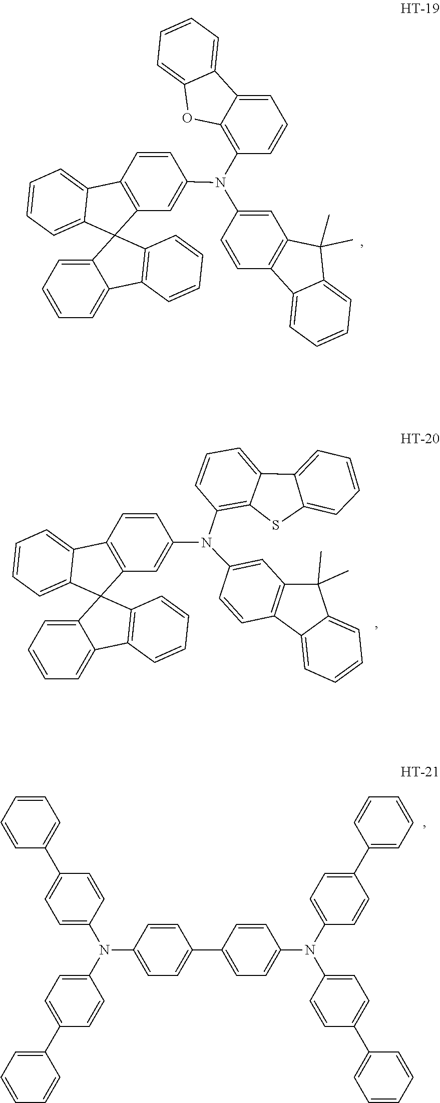 [SMILES: CC1(C)c2ccccc2-c2ccc(N(c3ccc4c(c3)C3(c5ccccc5-c5ccccc53)c3ccccc3-4)c3cccc4c3oc3ccccc34)cc21 ; CC1(C)c2ccccc2-c2ccc(N(c3ccc4c(c3)C3(c5ccccc5-c5ccccc53)c3ccccc3-4)c3cccc4c3sc3ccccc34)cc21 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

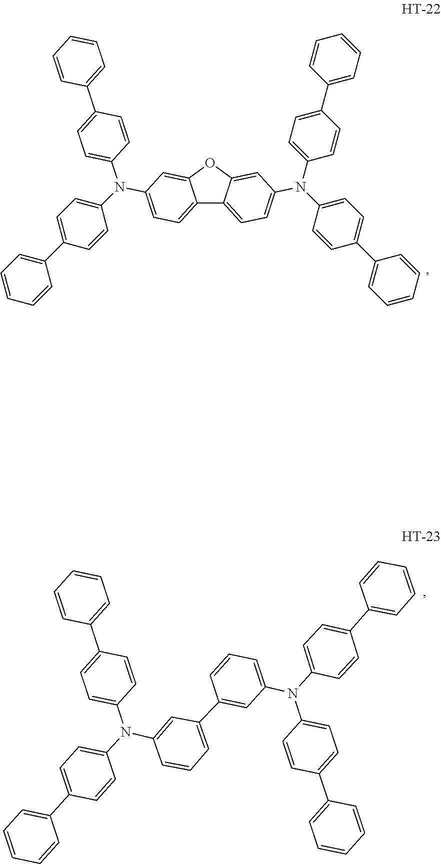 [SMILES: c1ccc(-c2ccc(N(c3ccc(-c4ccccc4)cc3)c3ccc4c(c3)oc3cc(N(c5ccc(-c6ccccc6)cc5)c5ccc(-c6ccccc6)cc5)ccc34)cc2)cc1 ; c1ccc(-c2ccc(N(c3ccc(-c4ccccc4)cc3)c3cccc(-c4cccc(N(c5ccc(-c6ccccc6)cc5)c5ccc(-c6ccccc6)cc5)c4)c3)cc2)cc1]

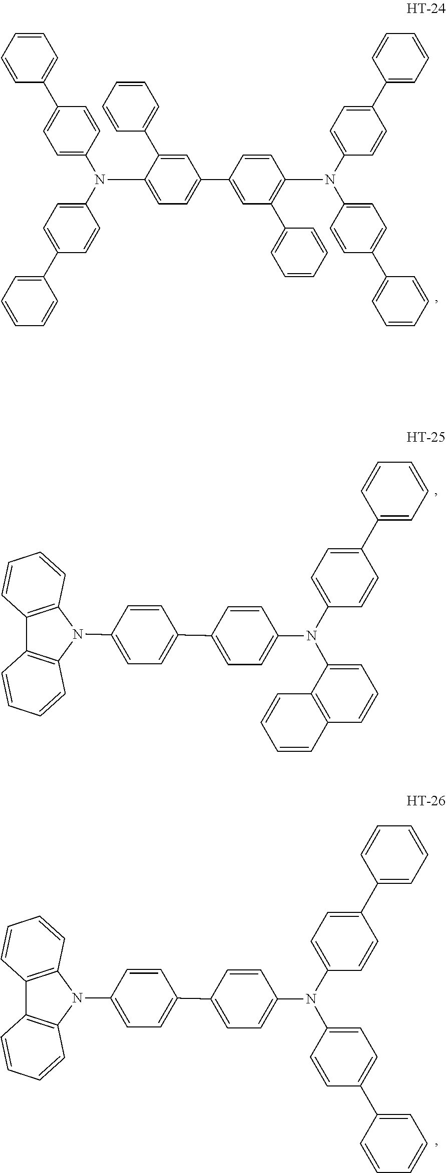 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)c(-c5ccccc5)c4)cc3-c3ccccc3)cc2)cc1 ; c1ccc(-c2ccc(N(c3ccc(-c4ccc(-n5c6ccccc6c6ccccc65)cc4)cc3)c3cccc4ccccc34)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

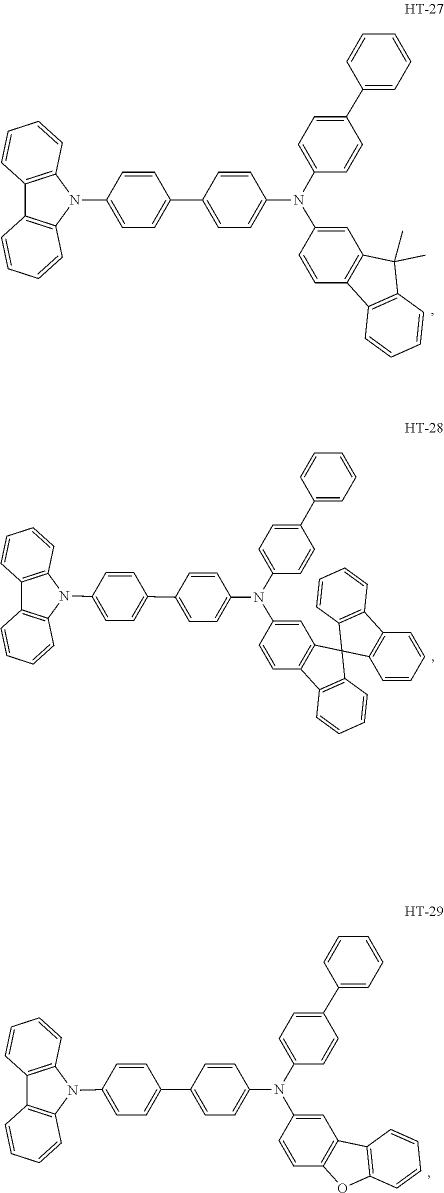 [SMILES: CC1(C)c2ccccc2-c2ccc(N(c3ccc(-c4ccccc4)cc3)c3ccc(-c4ccc(-n5c6ccccc6c6ccccc65)cc4)cc3)cc21 ; c1ccc(-c2ccc(N(c3ccc(-c4ccc(-n5c6ccccc6c6ccccc65)cc4)cc3)c3ccc4c(c3)C3(c5ccccc5-c5ccccc53)c3ccccc3-4)cc2)cc1 ; c1ccc(-c2ccc(N(c3ccc(-c4ccc(-n5c6ccccc6c6ccccc65)cc4)cc3)c3ccc4oc5ccccc5c4c3)cc2)cc1]

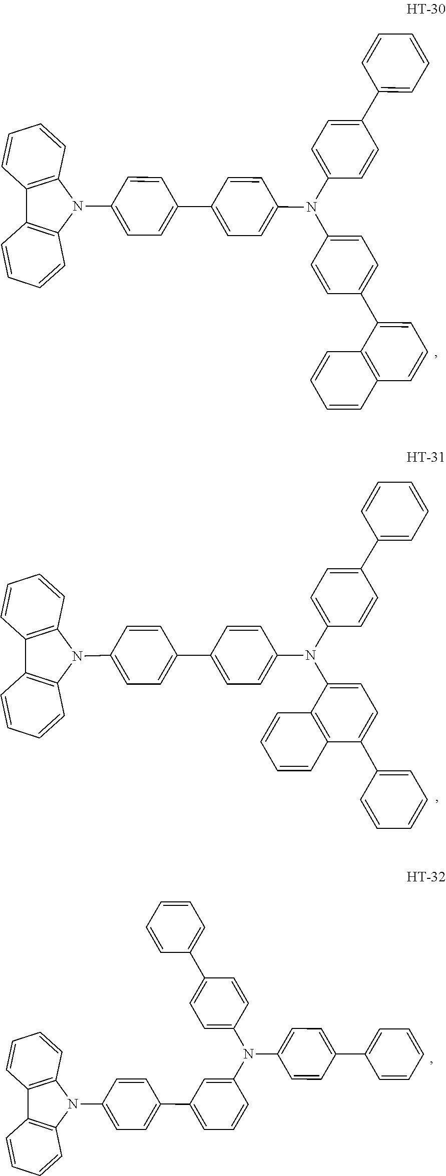 [SMILES: c1ccc(-c2ccc(N(c3ccc(-c4ccc(-n5c6ccccc6c6ccccc65)cc4)cc3)c3ccc(-c4cccc5ccccc45)cc3)cc2)cc1 ; c1ccc(-c2ccc(N(c3ccc(-c4ccc(-n5c6ccccc6c6ccccc65)cc4)cc3)c3ccc(-c4ccccc4)c4ccccc34)cc2)cc1 ; c1ccc(-c2ccc(N(c3ccc(-c4ccccc4)cc3)c3cccc(-c4ccc(-n5c6ccccc6c6ccccc65)cc4)c3)cc2)cc1]

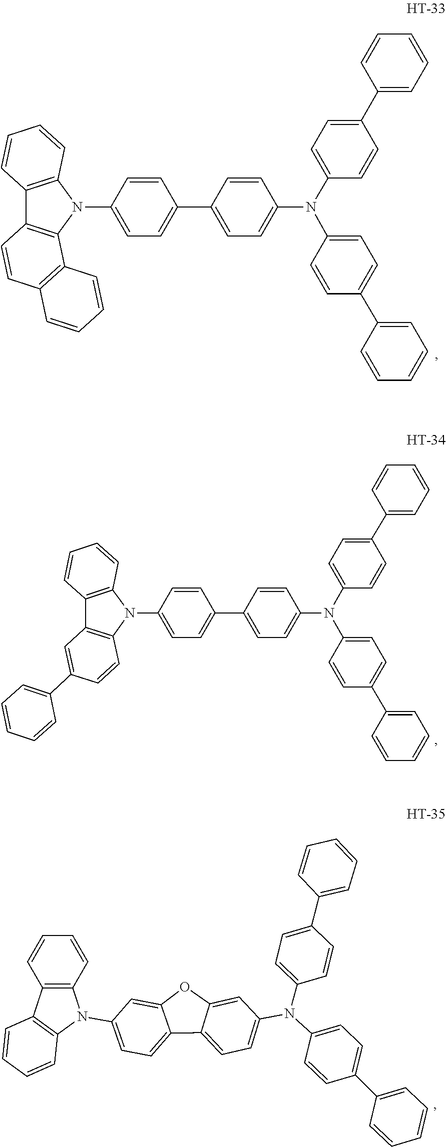 [SMILES: c1ccc(-c2ccc(N(c3ccc(-c4ccccc4)cc3)c3ccc(-c4ccc(-n5c6ccccc6c6ccc7ccccc7c65)cc4)cc3)cc2)cc1 ; c1ccc(-c2ccc(N(c3ccc(-c4ccccc4)cc3)c3ccc(-c4ccc(-n5c6ccccc6c6cc(-c7ccccc7)ccc65)cc4)cc3)cc2)cc1 ; c1ccc(-c2ccc(N(c3ccc(-c4ccccc4)cc3)c3ccc4c(c3)oc3cc(-n5c6ccccc6c6ccccc65)ccc34)cc2)cc1]

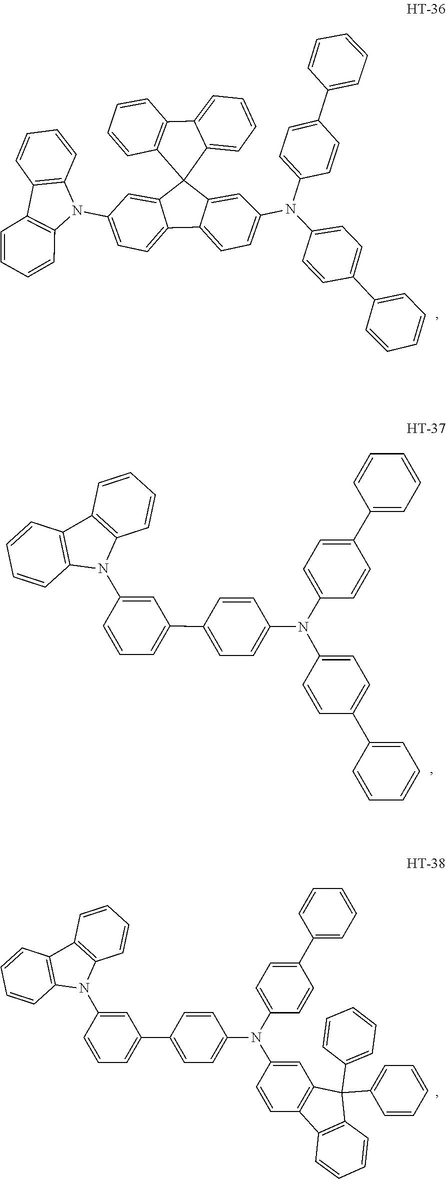 [SMILES: c1ccc(-c2ccc(N(c3ccc(-c4ccccc4)cc3)c3ccc4c(c3)C3(c5ccccc5-c5ccccc53)c3cc(-n5c6ccccc6c6ccccc65)ccc3-4)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3ccc(-c4cccc(-n5c6ccccc6c6ccccc65)c4)cc3)c3ccc4c(c3)C(c3ccccc3)(c3ccccc3)c3ccccc3-4)cc2)cc1]

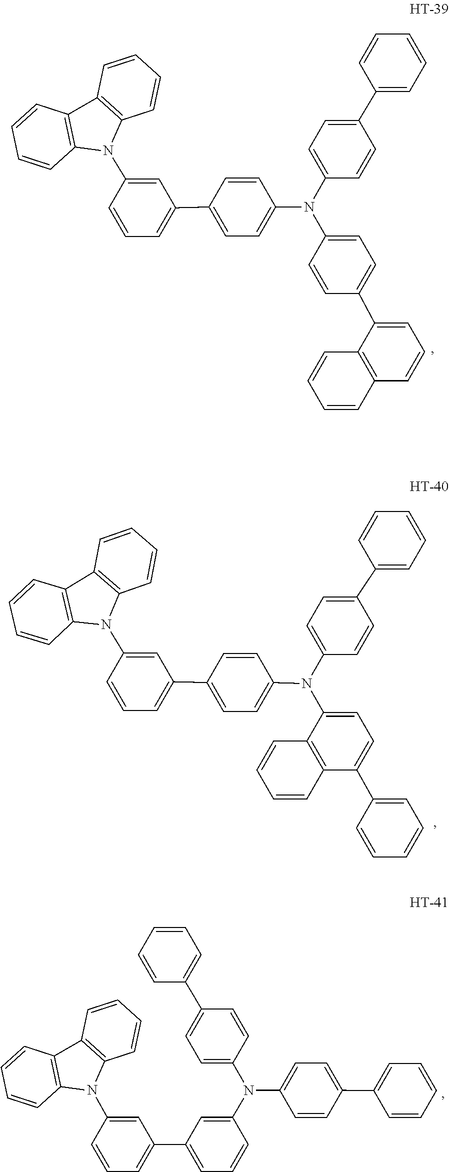 [SMILES: c1ccc(-c2ccc(N(c3ccc(-c4cccc(-n5c6ccccc6c6ccccc65)c4)cc3)c3ccc(-c4cccc5ccccc45)cc3)cc2)cc1 ; c1ccc(-c2ccc(N(c3ccc(-c4cccc(-n5c6ccccc6c6ccccc65)c4)cc3)c3ccc(-c4ccccc4)c4ccccc34)cc2)cc1 ; c1ccc(-c2ccc(N(c3ccc(-c4ccccc4)cc3)c3cccc(-c4cccc(-n5c6ccccc6c6ccccc65)c4)c3)cc2)cc1]

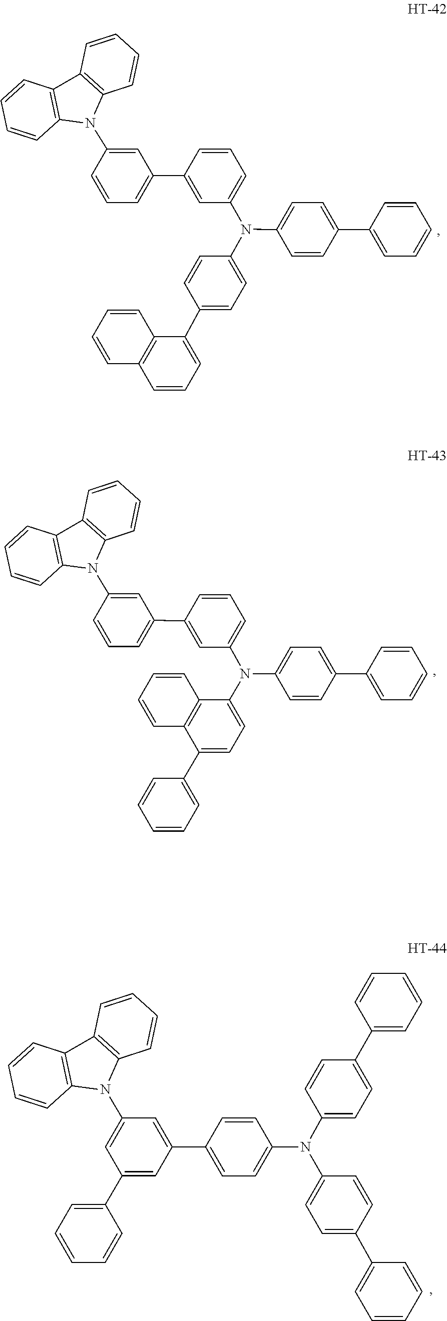 [SMILES: c1ccc(-c2ccc(N(c3ccc(-c4cccc5ccccc45)cc3)c3cccc(-c4cccc(-n5c6ccccc6c6ccccc65)c4)c3)cc2)cc1 ; c1ccc(-c2ccc(N(c3cccc(-c4cccc(-n5c6ccccc6c6ccccc65)c4)c3)c3ccc(-c4ccccc4)c4ccccc34)cc2)cc1 ; c1ccc(-c2ccc(N(c3ccc(-c4ccccc4)cc3)c3ccc(-c4cc(-c5ccccc5)cc(-n5c6ccccc6c6ccccc65)c4)cc3)cc2)cc1]

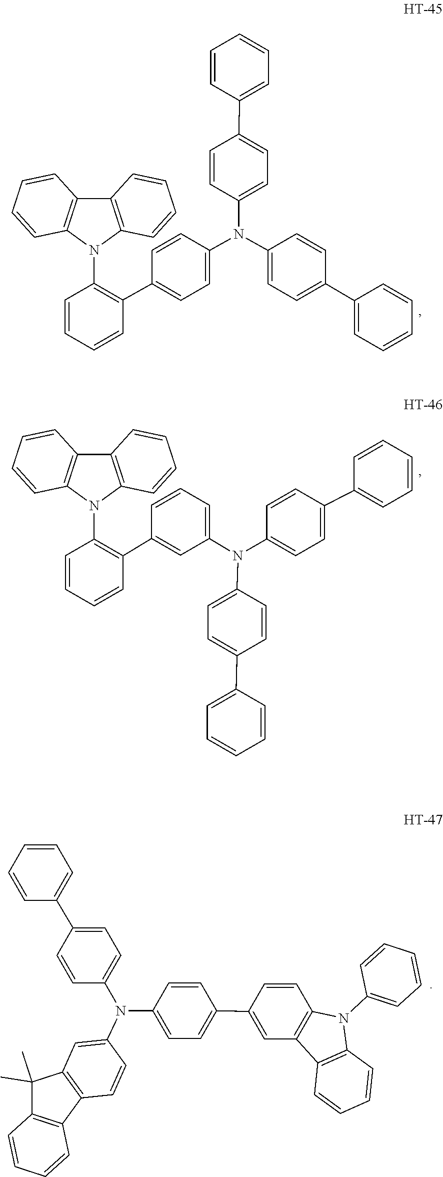 [SMILES: c1ccc(-c2ccc(N(c3ccc(-c4ccccc4)cc3)c3ccc(-c4ccccc4-n4c5ccccc5c5ccccc54)cc3)cc2)cc1 ; c1ccc(-c2ccc(N(c3ccc(-c4ccccc4)cc3)c3cccc(-c4ccccc4-n4c5ccccc5c5ccccc54)c3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

According to an embodiment of the present disclosure, an electronic assembly is disclosed, which comprises the organic electroluminescent device in any one of the preceding embodiments.

In terms of device structure, OLEDs can be classified into conventional OLEDs having a single-layer structure and OLEDs having a tandem structure (also called a stacked structure). The conventional OLED includes only one emissive unit between the cathode and the anode, while the tandem OLED includes multiple stacked emissive units. One emissive unit generally includes at least one emissive layer, one hole transporting layer, and one electron transporting layer. On this basis, the emissive unit may further include a hole injection layer, an electron injection layer, a hole blocking layer, and an electron blocking layer. It is to be noted that although the conventional single-layer OLED has only one emissive unit, this emissive unit may include multiple emissive layers, for example, the emissive unit may include one yellow emissive layer and one blue emissive layer. However, each emissive unit includes only one pair of a hole transporting layer and an electron transporting layer. The tandem OLED includes at least two emissive units, that is, the tandem OLED includes at least two pairs of hole transporting layers and electron transporting layers. Here, multiple emissive units are arranged in a vertically-stacked physical format to achieve a tandem circuit. Therefore, this type of OLED is referred to as a tandem OLED (in terms of the circuit connection) or a stacked OLED (in terms of the physical format). Under the same brightness, the tandem OLED requires a smaller current density than the conventional single-layer OLED, thereby prolonging a lifetime. On the contrary, at a constant current density, the tandem OLED provides higher brightness than the conventional single-layer OLED, with an increase in voltage. Adjacent emissive units of the tandem OLED are connected by a charge generation layer, and the quality of the charge generation layer directly affects parameters of the tandem OLED, such as voltage, lifetime, and efficiency. Therefore, the charge generation layer is required to be able to effectively generate holes and electrons and smoothly inject the holes and the electrons to corresponding emissive units and is also required to have greater transmittance in a visible light range and meanwhile have stable performance and be easy to prepare.

In the structure of a current commercial OLED, generally only one hole injection layer (HIL) is included, that is, a p-type dopant (PD) is doped with a hole transporting host material (HTM) at a certain ratio to form the HIL, or a single material, such as Compound HATCN

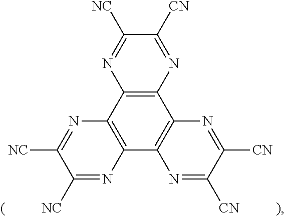 [SMILES: N#Cc1nc2c3nc(C#N)c(C#N)nc3c3nc(C#N)c(C#N)nc3c2nc1C#N]

is used to form the HIL. However, after such a single-layer structure works for a long time, the lifetime of the device is easy to decrease. To balance carriers in the device, multiple HILs are disclosed in the related art, which generally include only one p-type doped organic layer and another layer using a pure p-type material to promote hole injection. However, the regulation of a hole injection ability by the pure p-type material is uncontrollable, and an ability to regulate the hole injection is limited when the hole injection ability is regulated only by a change of a doping concentration of the p-type material in one layer. To balance electrons and holes in the OLED and solve the above-mentioned problems, the present application proposes the use of at least two organic layers comprising p-type dopants. This structure has a significant effect in improving the overall performance of the device.

Herein, the LUMO energy level and the HOMO energy level of a compound are measured by a cyclic voltammetry method. The measurement is conducted using an electrochemical workstation model No. ConTest CS120 produced by Wuhan Corrtest Instruments Corp., Ltd and using a three-electrode working system where a platinum disk electrode serves as a working electrode, a Ag/AgNO₃ electrode serves as a reference electrode, and a platinum wire electrode serves as an auxiliary electrode. With anhydrous DCM as a solvent and 0.1 mol/L tetrabutylammonium hexafluorophosphate as a supporting electrolyte, a target compound is prepared into a solution of 10⁻³ mol/L, and nitrogen is introduced into the solution for 10 min for oxygen removal before the measurement. The parameters of the instrument are set as follows: a scan rate of 100 mV/s, a potential interval of 0.5 mV, and a test window of 1 V to −0.5 V. The LUMO energy levels of some p-type dopants and the HOMO energy levels of organic materials were measured by the preceding test method. Data are recorded in Table 1.

TABLE 1
LUMO energy levels of some p-type dopants
and HOMO energy levels of organic materials

| Compound | LUMO (eV) | Compound | HOMO (eV) |
|---|---|---|---|
| 1-2 | −4.63 | HT-1 | −5.35 |
| 3-1 | −4.91 | HT-7 | −5.14 |
| 4-5 | −5.17 | HT-18 | −5.13 |
| 2-5 | −4.54 | HT-21 | −5.09 |
| 3-2 | −4.81 | HT-37 | −5.26 |
| 4-6 | −5.13 | HT-44 | −5.27 |
| 4-11 | −5.11 | HT-47 | −5.10 |
| PD1 | −5.04 | | |

The materials described herein as useful for a particular layer in an organic light-emitting device may be used in combination with a variety of other materials present in the device. For example, compounds disclosed herein may be used in combination with a wide variety of emissive dopants, hosts, transporting layers, blocking layers, injection layers, electrodes, and other layers that may be present. The combination of these materials is described in detail in paragraphs 0080-0101 of U.S. Pat. App. Pub. No. 20150349273, which is incorporated by reference herein in its entirety. The materials described or referred to the disclosure are non-limiting examples of materials that may be useful in combination with the compounds disclosed herein, and those skilled in the art can readily consult the literature to identify other materials that may be useful in combination.

In the examples of devices, the characteristics of the devices were also tested using conventional equipment in the art (including, but not limited to, an evaporator produced by ANGSTROM ENGINEERING, an optical testing system produced by SUZHOU FATAR, a lifetime testing system produced by SUZHOU FATAR, and an ellipsometer produced by BEIJING ELLITOP, etc.) by methods well-known to the persons skilled in the art. As the persons skilled in the art are aware of the above-mentioned equipment use, test methods, and other related contents, the inherent data of the sample can be obtained with certainty and without influence, so the above related contents are not further described in the present disclosure.

### EXAMPLE

The working principle of organic electroluminescence is specifically described below through several examples. Apparently, the following examples are only for the purpose of illustration and are not intended to limit the scope of the present disclosure. Based on the following examples, those skilled in the art can obtain other examples of the present disclosure by conducting improvements on these examples.

### Example 1-1

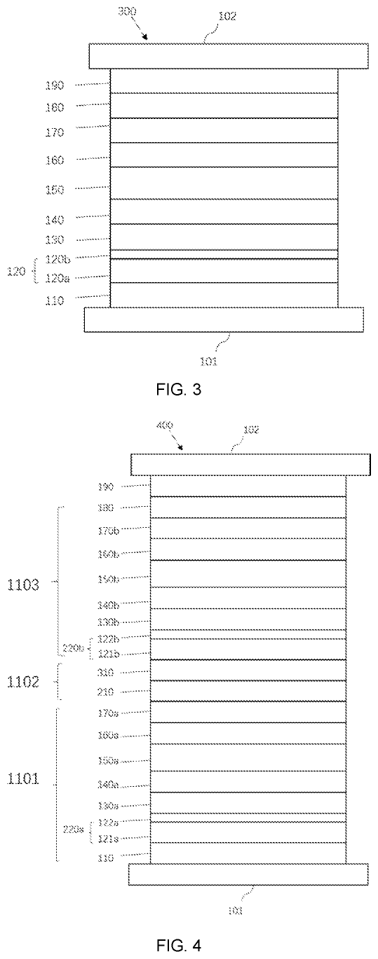

An organic electroluminescent device 300 comprising a first organic layer and a second organic layer of the present disclosure, as shown in the schematic diagram of FIG. 3, was prepared. (A hole blocking layer 160 was omitted in this example, and those skilled in the art can add the hole blocking layer as required.) The specific manner was described below. A glass substrate 101 having an indium tin oxide (ITO) anode 110 with a thickness of 1200 Å was cleaned, treated with UV ozone and oxygen plasma, dried in a nitrogen-filled glovebox to remove moisture, and then mounted on a substrate holder and placed in a vacuum chamber. Organic layers were sequentially deposited through vacuum thermal evaporation on the ITO anode at a rate of 0.01-10 Å/s and at a vacuum degree of about 10⁻⁶ Torr. HT-18 and Compound 3-1 were co-deposited for use as a first organic layer 120a with a thickness of 20 Å, where the doping proportion of Compound 3-1 was 2%. On the first organic layer 120a, HT-18 and Compound 1-2 were co-deposited for use as a second organic layer 120b with a thickness of 80 Å, where the doping proportion of Compound 1-2 was 16%. The first organic layer 120a and the second organic layer 120b were used together as a hole injection layer 120 with a total thickness of 100 Å. Compound HT-18 was deposited for use as a hole transporting layer (HTL) 130 with a thickness of 400 Å. Compound EB was deposited for use as an electron blocking layer (EBL) 140 with a thickness of 50 Å. A red emissive dopant, Compound D-1, was doped with a host compound RH to form a red emissive layer (EML) 150 with a thickness of 400 Å, where the doping proportion of Compound D-1 was 3%. Compound ET and LiQ were co-deposited for use as an electron transporting layer (ETL) 170 with a thickness of 350 Å, where the doping proportion of LiQ was 60%. On the ETL, LiQ was deposited for use as an electron injection layer (EIL) 180 with a thickness of 10 Å. Finally, Al was deposited for use as a cathode 190 with a thickness of 1200 Å. After evaporation, the device was transferred back to the glovebox and encapsulated with a glass lid 102 to complete the device.

### Example 1-2

The preparation process of Example 1-2 was the same as that of Example 1-1 except that the doping proportion of Compound 3-1 in the first organic layer 120a was 3%.

### Example 1-3

The preparation process of Example 1-3 was the same as that of Example 1-1 except that the first organic layer 120a was composed of Compound HT-18 and Compound 3-1 and had a thickness of 80 Å, and the doping proportion of Compound 3-1 was 0.5%; and the second organic layer 120b was also composed of Compound HT-18 and Compound 3-1 and had a thickness of 20 Å, and the doping proportion of Compound 3-1 was 3%.

### Example 1-4

The preparation process of Example 1-4 was the same as that of Example 1-1 except that the first organic layer 120a was composed of Compound HT-18 and Compound 1-2 and had a thickness of 80 Å, and the doping proportion of Compound 1-2 was 16%; and the second organic layer 120b was also composed of Compound HT-18 and Compound 1-2 and had a thickness of 20 Å, and the doping proportion of Compound 1-2 was 30%.

### Example 1-5

The preparation process of Example 1-5 was the same as that of Example 1-1 except that the first organic layer 120a was composed of Compound HT-18 and Compound 4-5 and had a thickness of 80 Å, and the doping proportion of Compound 4-5 was 3%; and the second organic layer 120b was composed of Compound HT-18 and Compound 1-2 and had a thickness of 20 Å, and the doping proportion of Compound 1-2 was 12%.

### Example 1-6

The preparation process of Example 1-6 was the same as that of Example 1-1 except that the first organic layer 120a was composed of Compound HT-18 and Compound 1-2 and had a thickness of 50 Å, and the doping proportion of Compound 1-2 was 30%; and the second organic layer 120b was composed of Compound HT-18 and Compound 1-2 and had a thickness of 50 Å, and the doping proportion of Compound 1-2 was 16%.

### Comparative Example 1-1

The preparation process of Comparative Example 1-1 was the same as that of Example 1-1 except that HT-18 and Compound 3-1 were co-deposited for use as the hole injection layer 120 with a thickness of 100 Å, and the doping proportion of Compound 3-1 was 0.5%.

### Comparative Example 1-2

The preparation process of Comparative Example 1-2 was the same as that of Comparative Example 1-1 except that HT-18 and Compound 3-1 were co-deposited for use as the hole injection layer 120 with a thickness of 100 Å, and the doping proportion of Compound 3-1 was 2%.

### Comparative Example 1-3

The preparation process of Comparative Example 1-3 was the same as that of Comparative Example 1-1 except that HT-18 and Compound 3-1 were co-deposited for use as the hole injection layer 120 with a thickness of 100 Å, and the doping proportion of Compound 3-1 was 3%.

### Comparative Example 1-4

The preparation process of Comparative Example 1-4 was the same as that of Comparative Example 1-1 except that HT-18 and Compound 1-2 were co-deposited for use as the hole injection layer 120 with a thickness of 100 Å, and the doping proportion of Compound 1-2 was 12%.

### Comparative Example 1-5

The preparation process of Comparative Example 1-5 was the same as that of Comparative Example 1-1 except that HT-18 and Compound 1-2 were co-deposited for use as the hole injection layer 120 with a thickness of 100 Å, and the doping proportion of Compound 1-2 was 16%.

### Comparative Example 1-6

The preparation process of Comparative Example 1-6 was the same as that of Comparative Example 1-1 except that HT-18 and Compound 4-5 were co-deposited for use as the hole injection layer 120 with a thickness of 100 Å, and the doping proportion of Compound 4-5 was 3%.

### Comparative Example 1-7

The preparation process of Comparative Example 1-7 was the same as that of Comparative Example 1-1 except that HT-18 and Compound PD1 were co-deposited for use as the hole injection layer 120 with a thickness of 100 Å, and the doping proportion of Compound PD1 was 16%.

### Comparative Example 1-8

The preparation process of Comparative Example 1-8 was the same as that of Comparative Example 1-1 except that HT-18 and Compound PD1 were co-deposited for use as the hole injection layer 120 with a thickness of 100 Å, and the doping proportion of Compound PD1 was 30%.

### Comparative Example 1-9

The preparation process of Comparative Example 1-9 was the same as that of Example 1-1 except that the first organic layer 120a was composed of Compound HT-18 and Compound PD1 and had a thickness of 50 Å, and the doping proportion of Compound PD1 was 30%; and the second organic layer 120b was composed of Compound HT-18 and Compound PD1 and had a thickness of 50 Å, and the doping proportion of Compound PD1 was 16%.

### Comparative Example 1-10

The preparation process of Comparative Example 1-10 was the same as that of Example 1-1 except that the first organic layer 120a was composed of Compound 3-1 and had a thickness of 80 Å; and the second organic layer 120b was composed of Compound HT-18 and Compound 3-1 and had a thickness of 20 Å, and the doping proportion of Compound 3-1 was 3%.

### Comparative Example 1-11

The preparation process of Comparative Example 1-11 was the same as that of Example 1-1 except that the first organic layer 120a was composed of Compound HT-18 and Compound 3-1 and had a thickness of 20 Å, and the doping proportion of Compound 3-1 was 3%; and the second organic layer 120b was composed of Compound 3-1 and had a thickness of 80 Å.

Details of the first organic layers and the second organic layers in the devices of Examples 1-1 to 1-6 and Comparative Examples 1-1 to 1-11 are shown in Table 2. A layer using more than one material is obtained by doping different compounds at their weight ratio as recorded.

TABLE 2
Structures of the first organic layers and the second organic layers
in Examples 1-1 to 1-6 and Comparative Examples 1-1 to 1-11

| Device No. | First Organic layer | Second Organic layer |
|---|---|---|
| Example 1-1 | HT-18:Compound 3-1 = 98:2 (20 Å) | HT-18:Compound 1-2 = 84:16 (80 Å) |
| Example 1-2 | HT-18:Compound 3-1 = 97:3 (20 Å) | HT-18:Compound 1-2 = 84:16 (80 Å) |
| Example 1-3 | HT-18:Compound 3-1 = 99.5:0.5 (80 Å) | HT-18:Compound 3-1 = 97:3 (20 Å) |
| Example 1-4 | HT-18:Compound 1-2 = 84:16 (80 Å) | HT-18:Compound 1-2 = 70:30 (20 Å) |
| Example 1-5 | HT-18:Compound 4-5 = 97:3 (80 Å) | HT-18:Compound 1-2 = 88:12 (20 Å) |
| Example 1-6 | HT-18:Compound 1-2 = 70:30 (50 Å) | HT-18:Compound 1-2 = 84:16 (50 Å) |
| Comparative | HT-18:Compound 3-1 = 99.5:0.5 (100 Å) | |
| Example 1-1 | | |
| Comparative | HT-18:Compound 3-1 = 98:2 (100 Å) | |
| Example 1-2 | | |
| Comparative | HT-18:Compound 3-1 = 97:3 (100 Å) | |
| Example 1-3 | | |
| Comparative | HT-18:Compound 1-2 = 88:12 (100 Å) | |
| Example 1-4 | | |
| Comparative | HT-18:Compound 1-2 = 84:16 (100 Å) | |
| Example 1-5 | | |
| Comparative | HT-18:Compound 4-5 = 97:3 (100 Å) | |
| Example 1-6 | | |
| Comparative | HT-18:Compound PD1 = 84:16 (100 Å) | |
| Example 1-7 | | |
| Comparative | HT-18:Compound PD1 = 70:30 (100 Å) | |
| Example 1-8 | | |
| Comparative | HT-18:Compound PD1 = 70:30 (50 Å) | HT-18:Compound PD1 = 84:16 (50 Å) |
| Example 1-9 | | |
| Comparative | Compound 3-1 (80 Å) | HT-18:Compound 3-1 = 97:3 (20 Å) |
| Example 1-10 | | |
| Comparative | HT-18:Compound 3-1 = 97:3 (20 Å) | Compound 3-1 (80 Å) |
| Example 1-11 | | |

The structures of the compounds used in the devices are shown as follows:

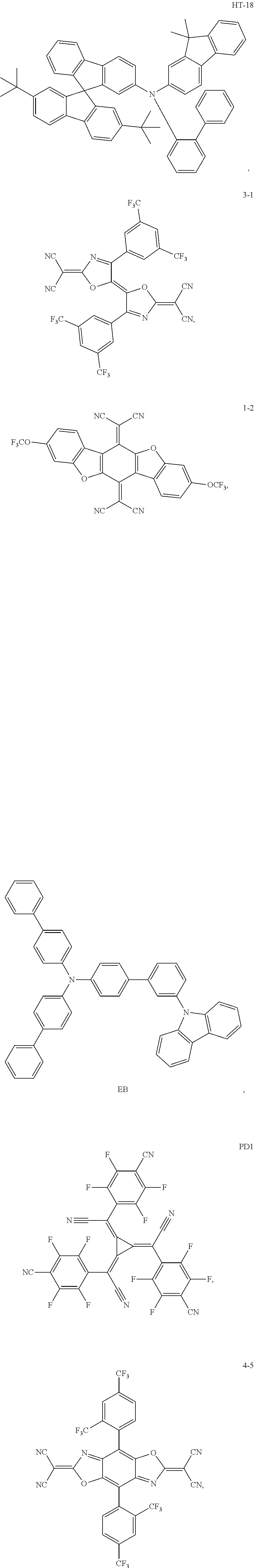

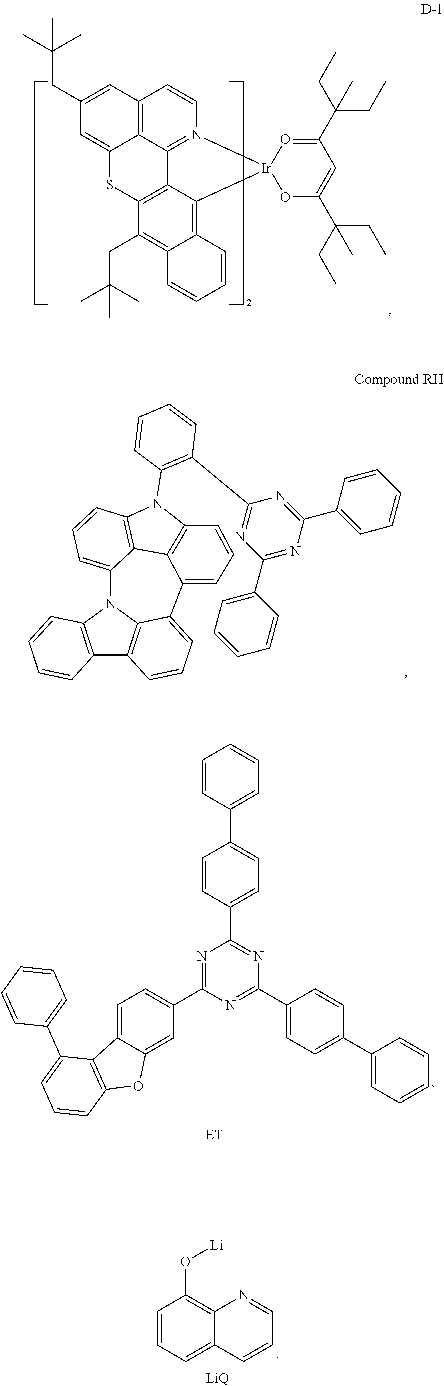

The device performance of Examples 1-1 to 1-6 and Comparative Examples 1-1 to 1-11 was measured. Color coordinates (CIE), voltages, and external quantum efficiency (EQE) were measured at a current density of 10 mA/cm², and a device lifetime (LT95) was a measured time taken for the device to decay to 97% of initial brightness at a constant current density of 80 mA/cm². These data are shown in Table 3.

TABLE 3
Device data of Examples 1-1 to 1-6 and
Comparative Examples 1-1 to 1-11

| | 10 mA/cm² | | | 80 mA/cm² |
|---|---|---|---|---|
| | CIE | Voltage | EQE | LT97 |
| Device No. | (x, y) | (V) | (%) | (h) |
| Example 1-1 | (0.701, 0.298) | 3.1 | 27.8 | 283 |
| Example 1-2 | (0.701, 0.298) | 3.1 | 27.4 | 298 |
| Example 1-3 | (0.701, 0.298) | 3.2 | 28.4 | 250 |
| Example 1-4 | (0.700, 0.299) | 2.9 | 27.0 | 350 |
| Example 1-5 | (0.701, 0.299) | 2.9 | 26.2 | 300 |
| Example 1-6 | (0.700, 0.299) | 3.2 | 28.5 | 232 |
| Comparative | (0.701, 0.298) | 3.6 | 31.7 | 140 |
| Example 1-1 | | | | |
| Comparative | (0.701, 0.298) | 3.0 | 27.2 | 216 |
| Example 1-2 | | | | |
| Comparative | (0.701, 0.298) | 3.0 | 26.3 | 209 |
| Example 1-3 | | | | |
| Comparative | (0.701, 0.298) | 3.9 | 36.1 | 36 |
| Example 1-4 | | | | |
| Comparative | (0.701, 0.299) | 4.0 | 32.6 | 50 |
| Example 1-5 | | | | |
| Comparative | (0.701, 0.299) | 2.9 | 25.9 | 196 |
| Example 1-6 | | | | |
| Comparative | (0.701, 0.299) | 3.0 | 26.0 | 130 |
| Example 1-7 | | | | |
| Comparative | (0.701, 0.299) | 3.0 | 25.9 | 130 |
| Example 1-8 | | | | |
| Comparative | (0.701, 0.299) | 3.0 | 25.9 | 130 |
| Example 1-9 | | | | |
| Comparative | (0.701, 0.298) | 2.9 | 23.5 | 220 |
| Example 1-10 | | | | |
| Comparative | (0.701, 0.298) | 2.8 | 23.1 | 240 |
| Example 1-11 | | | | |

As can be seen from the device data in Table 3, the color coordinates of the shown examples are basically consistent with those of the comparative examples.

An OLED with high EQE, a low voltage, and a long lifetime are an expected good device, but the overall performance of the device should be considered when the high EQE, low voltage, and long lifetime cannot be achieved at the same time. In Example 1-1, the first organic layer and the second organic layer were in contact with each other, the first organic layer was composed of a first p-type dopant, Compound 3-1, and HT-18 with a doping proportion of 2%, and the second organic layer was composed of a second p-type dopant, Compound 1-2, and HT-18 with a doping proportion of 16%. Example 1-1 achieved a high EQE of 27.8%, an ultra-long lifetime of 283 h, and a driving voltage of 3.1 V. Example 1-1 was compared with Comparative Example 1-2 and Comparative Example 1-5 separately for analysis. (1) Comparative Example 1-2 included only one p-type doped layer the same as the first organic layer in Example 1-1 (where the p-type doped layer and the first organic layer used the same materials and had the same doping proportion). Compared with Comparative Example 1-2, Example 1-1 had EQE slightly increased by 2% and a lifetime greatly increased by 31%. (2) Comparative Example 1-5 included only one p-type doped layer the same as the second organic layer in Example 1-1 (where the p-type doped layer and the second organic layer used the same materials and had the same doping proportion). Compared with Comparative Example 1-5, Example 1-1 had a lower voltage reduced by 0.9 V and a surprising lifetime tremendously increased by 466%. Example 1-1 achieved a high EQE of 27.8%, which is, although lower than Comparative Example 1-5, considered as a relatively high efficiency level in the industry. In view of the high voltage and an extremely short lifetime of Comparative Example 1-5, therefore Example 1-1 was a device with better overall performance.

In Example 1-2, the first organic layer and the second organic layer were in contact with each other, the first organic layer was composed of a first p-type dopant, Compound 3-1, and HT-18 with a doping proportion of 3%, and the second organic layer was composed of a second p-type dopant, Compound 1-2, and HT-18 with a doping proportion of 16%. Example 1-2 achieved a high EQE of 27.4%, a low driving voltage of 3.1 V, and an ultra-long lifetime of 298 h. Example 1-2 was compared with Comparative Example 1-3 and Comparative Example 1-5 separately for analysis. (1) Comparative Example 1-3 included only one p-type doped layer the same as the first organic layer in Example 1-2 (where the p-type doped layer and the first organic layer used the same materials and had the same doping proportion). Compared with Comparative Example 1-3, Example 1-2 had EQE increased by about 5%, a lifetime increased by 43%, and a similar driving voltage. (2) Comparative Example 1-5 included only one p-type doped layer the same as the second organic layer in Example 1-2 (where the p-type doped layer and the second organic layer used the same materials and had the same doping proportion). Compared with Comparative Example 1-5, Example 1-2 had a driving voltage reduced by 23% and a lifetime increased by 496%. Example 1-2 achieved a high EQE of 27.4%, which is, although lower than Comparative Example 1-5, considered as a relatively high efficiency level in the industry. In view of the high voltage and an extremely short lifetime of Comparative Example 1-5, therefore Example 1-2 was a device with better overall performance.

In Example 1-3, the first organic layer and the second organic layer were in contact with each other, the first organic layer was composed of a first p-type dopant, Compound 3-1, and HT-18 with a doping proportion of 0.5%, and the second organic layer was composed of a second p-type dopant, Compound 3-1, and HT-18 with a doping proportion of 3%. Example 1-3 achieved a relatively low driving voltage of 3.2 V, a high efficiency of 28.4%, and a long lifetime of 250 h. Example 1-3 is compared with Comparative Example 1-1 and Comparative Example 1-3 separately for analysis. (1) Comparative Example 1-1 included only one p-type doped layer the same as the first organic layer in Example 1-3 (where the p-type doped layer and the first organic layer used the same materials and had the same doping proportion). Compared with Comparative Example 1-1, Example 1-3 had a driving voltage reduced by 0.4 V and a lifetime increased by 79%. Although Example 1-3 had lower efficiency than Comparative Example 1-1, Example 1-3 reached a high EQE level of 28.4% and had the overall performance advantages of a low voltage and a long lifetime. (2) Comparative Example 1-3 included only one p-type doped layer the same as the second organic layer in Example 1-3 (where the p-type doped layer and the second organic layer used the same materials and had the same doping proportion). Compared with Comparative Example 1-3, Example 1-3 had EQE increased by 8%, a lifetime increased by 20%, and a similar driving voltage. The overall performance of Example 1-3 was greatly improved.

Similarly, compared with Comparative Example 1-5 having only the first organic layer, Example 1-4 had a driving voltage reduced by 1.1 V and a lifetime increased by 6 times. Although Example 1-4 had slightly reduced EQE, the resulting EQE of 27% is considered as a relatively high efficiency level in the industry. The overall performance of Example 1-4 is greatly improved.

Compared with Comparative Example 1-6 having only the first organic layer and Comparative Example 1-4 having only the second organic layer, Example 1-5 had a lifetime increased by 53% and 7.3 times, respectively. Compared with Comparative Example 1-4, Example 1-5 had a driving voltage reduced by 1.0 V. Although Example 1-5 had slightly reduced EQE, the resulting EQE of 26.2% is considered as a relatively high efficiency level in the industry. The overall performance of Example 1-5 was greatly improved. Compared with Comparative Example 1-6, Example 1-5 has a similar driving voltage and slightly improved EQE.

Compared with Comparative Example 1-5 having only the second organic layer, Example 1-6 had a lifetime increased by 3.64 times and a driving voltage reduced by 0.8 V. Although Example 1-6 had slightly reduced EQE, the resulting EQE of 28.5% is considered as a relatively high efficiency level in the industry. The overall performance of Example 1-6 was greatly improved.

It can be found from the preceding comparison that an OLED comprising the first organic layer and the second organic layer satisfying particular conditions of the present disclosure can achieve excellent overall performance.

The devices in Comparative Examples 1-7 to 1-9 used a p-type dopant not provided by the present disclosure. Comparative Example 1-9 used a first organic layer and a second organic layer each comprising the p-type dopant not provided by the present disclosure, while Comparative Example 1-7 and Comparative Example 1-8 used the second organic layer and the first organic layer in Comparative Example 1-9, respectively. As can be seen from the data in Table 3, Comparative Examples 1-7 to 1-9 had substantially the same device performance, indicating that when the p-type dopant not provided by the present disclosure is applied to a device comprising multiple organic layers with p-type dopants, the device has no improvement in device performance compared with the device comprising a single layer with the p-type dopant. Meanwhile, Example 1-6 and Comparative Example 1-9 both included the first organic layer and the second organic layer but used different p-type dopants, where Example 1-6 used the p-type dopant of the present disclosure, Compound 1-2, while Comparative Example 1-9 used PD1 not provided by the present disclosure as the p-type dopant. Example 1-6 had a device lifetime increased by 78%, EQE increased by 10%, and a driving voltage slightly increased by V. Example 1-6 had better overall device performance. Therefore, it can be seen that Example 1-6 indicates that the device of the present disclosure comprising a particular p-type dopant and having a particular structure has better device performance.

Example 1-3 was compared with Comparative Examples 1-10 and 1-11 separately. The first organic layer or the second organic layer in Comparative Examples 1-10 and 1-11 was an organic layer comprising only the p-type dopant (Compound 3-1) of the present application, rather than an organic layer comprising the p-type dopant doped with another organic material. Compared with Comparative Examples 1-10 and 1-11, Example 1-3 had EQE increased by more than 20%, and an increased lifetime. Although the driving voltage was slightly increased, it can be seen that Example 1-3 had better overall device performance.

As can be seen from the preceding comparison and discussion of Examples 1-1 to 1-6 and Comparative Examples 1-1 to 1-11, the device of the present disclosure comprising a particular p-type dopant and having a particular structure had better overall device performance.

Example 2-1: An organic electroluminescent device 400 comprising stacked layers of the present disclosure, as shown in FIG. 4, was prepared. (Hole blocking layers 160a and 160b were omitted in this example, and those skilled in the art can add the hole blocking layers as required.) The specific manner was described below. A glass substrate 101 which was previously coated with a patterned indium tin oxide (ITO) anode 110 with a thickness of 1200 Å was cleaned with ultrapure water, and the ITO surface was treated with UV ozone and oxygen plasma. The substrate was dried in a nitrogen-filled glovebox to remove moisture, then mounted on a holder, and placed in an evaporation chamber. Organic layers specified below were sequentially deposited through vacuum thermal evaporation on the ITO anode at a rate of 0.01-10 Å/s and at a vacuum degree of about 1*10⁻⁶ Torr. A first emissive unit 1101 was deposited. HT-18 and Compound 3-1 were co-deposited for use as a first organic layer 121a with a thickness of 20 Å, where the doping proportion of Compound 3-1 was 3%. On the first organic layer 121a, HT-18 and Compound 1-2 were co-deposited for use as a second organic layer 122a with a thickness of 80 Å, where the doping proportion of Compound 1-2 was 16%. The first organic layer 121a and the second organic layer 122a were used together as a hole injection layer 220a of the first emissive unit 1101 having a total thickness of 100 Å. Compound HT-18 was deposited for use as a hole transporting layer (HTL) 130a with a thickness of 400 Å. Compound EB was deposited for use as an electron blocking layer (EBL) 140a with a thickness of 50 Å. A red emissive dopant, Compound D-1, was doped with a host compound RH to form a red emissive layer (EML) 150a with a thickness of 400 Å, where the doping proportion of Compound D-1 was 3%. Compound ET and LiQ were co-deposited for use as an electron transporting layer (ETL) 170a with a thickness of 350 Å, where the doping proportion of LiQ was 60%. A charge generation layer 1102 was deposited. On the ETL, a metal Yb was deposited for use as an n-type charge generation layer 210 with a thickness of 15 Å, and Compound 1-2 was deposited for use as a p-type charge generation layer 310 with a thickness of 30 Å. A second emissive unit 1103 was deposited. HT-18 and Compound 3-1 were co-deposited for use as a first organic layer 121b with a thickness of 20 Å, where the doping proportion of Compound 3-1 was 3%. On the first organic layer 121b, HT-18 and Compound 1-2 were co-deposited for use as a second organic layer 122b with a thickness of 80 Å, where the doping proportion of Compound 1-2 was 16%. The first organic layer 121b and the second organic layer 122b were used together as a hole injection layer 220b of the second emissive unit 1103 having a total thickness of 100 Å. Compound HT-18 was deposited for use as an HTL 130b with a thickness of 400 Å. Compound EB was deposited for use as an electron blocking layer (EBL) 140b with a thickness of 50 Å. A red emissive dopant, Compound D-1, was doped with a host compound RH to form a red emissive layer (EML) 150b with a thickness of 400 Å, where the doping proportion of Compound D-1 was 3%. Compound ET and LiQ were co-deposited for use as an electron transporting layer (ETL) 170b with a thickness of 350 Å, where the doping proportion of LiQ was 60%. Finally, Compound EIL was deposited for use as an electron injection layer (EIL) 180 with a thickness of 10 Å, and Al was deposited for use as a cathode 190 with a thickness of 1200 Å.

It is to be noted that the stacked device structure is only an example and is not limited to the description of the present disclosure. For example, the hole injection layer 220a of the first emissive unit 1101 may have a different structure from that of the second emissive unit 1103. For another example, the second emissive unit 1103 may use a host compound and a emissive material of another color as well as a corresponding transporting material and device structure.

### Comparative Example 2-1

The preparation process of Comparative Example 2-1 was the same as that of Example 2-1 except that the hole injection layer 220a of the first emissive unit and the hole injection layer 220b of the second emissive unit each comprise only the first organic layer composed of HT-18 and Compound 3-1 and having a thickness of 100 Å, and the doping proportion of Compound 3-1 was 3%.

### Comparative Example 2-2

The preparation process of Comparative Example 2-2 was the same as that of Example 2-1 except that the hole injection layer 220a of the first emissive unit and the hole injection layer 220b of the second emissive unit each comprise only the second organic layer composed of HT-18 and Compound 1-2 and having a thickness of 100 Å, and the doping proportion of Compound 1-2 was 16%.

Details of some device structures in Example 2-1 and Comparative Examples 2-1 to 2-2 are shown in Table 4. A layer using more than one material is obtained by doping different compounds at their weight ratio as recorded.

TABLE 4
Some device structures in Example 2-1 and Comparative Examples 2-1 to 2-2

| | First Emissive unit | | Second Emissive unit | |
|---|---|---|---|---|
| | First Organic | Second Organic | First Organic | Second Organic |
| Device No. | Layer 121a | Layer 122a | Layer 121b | Layer 122b |
| Example 2-1 | HT-18:Compound | HT-18:Compound | HT-18:Compound | HT-18:Compound |
| | 3-1 = 97:3 (20 Å) | 1-2 = 84:16 (80 Å) | 3-1 = 97:3 (20 Å) | 1-2 = 84:16 (80 Å) |
| Comparative | HT-18:Compound 3-1 = 97:3 (100 Å) | | HT-18:Compound 3-1 = 97:3 (100 Å) | |
| Example 2-1 | | | | |
| Comparative | HT-18:Compound 1-2 = 84:16 (100 Å) | | HT-18:Compound 1-2 = 84:16 (100 Å) | |
| Example 2-2 | | | | |

The device performance of Example 2-1 and Comparative Examples 2-1 to 2-2 was measured. Color coordinates (CIE), voltages, and external quantum efficiency (EQE) were measured at a brightness of 2000 cd/m², and a device lifetime was a time taken for the device to decay to 97% of initial brightness at 80 mA/cm². These data are shown in Table 5.

TABLE 5
Device performance of Example 2-1
and Comparative Examples 2-1 to 2-2

| | 2000 cd/m² | | | 80 mA/cm² |
|---|---|---|---|---|
| | CIE | Voltage | EQE | LT97 |
| Device No. | (x, y) | (V) | (%) | (h) |
| Example 2-1 | (0.701, 0.298) | 5.7 | 56.1 | 250 |
| Comparative | (0.701, 0.298) | 5.7 | 50.6 | 218 |
| Example 2-1 | | | | |
| Comparative | (0.701, 0.298) | 5.9 | 58.4 | 158 |
| Example 2-2 | | | | |

Example 2-1 is a stacked OLED where two emissive units were connected by the charge generation layer, the first emissive unit and the second emissive unit each comprised the first organic layer and the second organic layer, the first organic layer was composed of HT-18 and Compound 3-1, and the doping proportion of Compound 3-1 was 3%; and the second organic layer was composed of HT-18 and Compound 1-2, and the doping proportion of Compound 1-2 was 16%. Example 2-1 achieved a relatively high EQE of 56.1% and a low voltage of 5.7 V at 2000 cd/m² and an ultra-long lifetime of 250 h. The first emissive unit and the second emissive unit in Comparative Examples 2-1 and 2-2 each comprise only the first organic layer or the second organic layer in Example 2-1 (with the same materials and the same doping proportion). Compared with Comparative Examples 2-1 and 2-2, Example 2-1 had a lifetime increased by 14.6% and 58.2% and a similar driving voltage. Compared with Comparative Example 2-1, Example 2-1 had EQE increased by 10.8%. Although the efficiency of Example 2-1 was slightly lower than that of Comparative Example 2-2 by 4%, the improvement in lifetime was more significant.

It can be seen that the first organic layer and the second organic layer of the present disclosure comprising a particular structural composition can improve the overall performance of the stacked device.

### Example 3-1

An organic electroluminescent device 300, as shown in FIG. 3, was prepared. The specific manner was described below. A glass substrate 101 having an indium tin oxide (ITO) anode 110 with a thickness of 800 Å was cleaned, treated with UV ozone and oxygen plasma, dried in a nitrogen-filled glovebox to remove moisture, and then mounted on a substrate holder and placed in a vacuum chamber. Organic layers were sequentially deposited through vacuum thermal evaporation on the ITO anode at a rate of 0.01-10 Å/s and at a vacuum degree of about 10⁻⁶ Torr. HT-18 and Compound 3-1 were co-deposited for use as a first organic layer 120a with a thickness of 20 Å, where the doping proportion of Compound 3-1 was 3%. On the first organic layer 120a, HT-18 and Compound 1-2 were co-deposited for use as a second organic layer 120b with a thickness of 80 Å, where the doping proportion of Compound 1-2 was 16%. The first organic layer 120a and the second organic layer 120b were used together as a hole injection layer 120 with a total thickness of 100 Å. Compound HT-18 was deposited for use as a hole transporting layer (HTL) with a thickness of 250 Å. Compound HT-1 was used as an electron blocking layer (EBL) with a thickness of 50 Å. A blue light dopant, Compound D-2, and a blue light host compound BH were doped and co-deposited for use as a blue emissive layer (EML) with a total thickness of 250 Å, where the doping proportion of Compound D-2 was 4%. Compound HB was deposited for use as a hole blocking layer (HBL) with a thickness of 50 Å. On the HBL, Compound ET1 and LiQ were co-deposited for use as an electron transporting layer (ETL) with a thickness of 300 Å, where LiQ accounted for 60% of the total weight of the ETL. On the ETL, LiQ was deposited for use as an electron injection layer (EIL) with a thickness of 10 Å. Finally, Al was deposited for use as a cathode with a thickness of 1200 Å. After evaporation, the device was transferred back to the glovebox and encapsulated with a glass lid to complete the device.

### Comparative Example 3-1

The preparation process of Comparative Example 3-1 was the same as that of Example 3-1 except that the hole injection layer 120 comprises only the first organic layer composed of HT-18 and Compound 3-1 and having a thickness of 100 Å, and Compound 3-1 accounted for 3% of the total weight of the HIL.

Details of some device structures in Example 3-1 and Comparative Example 3-1 are shown in Table 6. A layer using more than one material is obtained by doping different compounds at their weight ratio as recorded.

TABLE 6
Some device structures in Example
3-1 and Comparative Example 3-1

| Device No. | First Organic layer 120a | Second Organic layer 120b |
|---|---|---|
| Example 3-1 | HT-18:Compound 3-1 = | HT-18:Compound 1-2 = |
| | 97:3 (20 Å) | 84:16 (80 Å) |
| Comparative | HT-18:Compound 3-1 = 97:3 (100 Å) | |
| Example 3-1 | | |

The structures of the new compounds used in the devices are shown as follows:

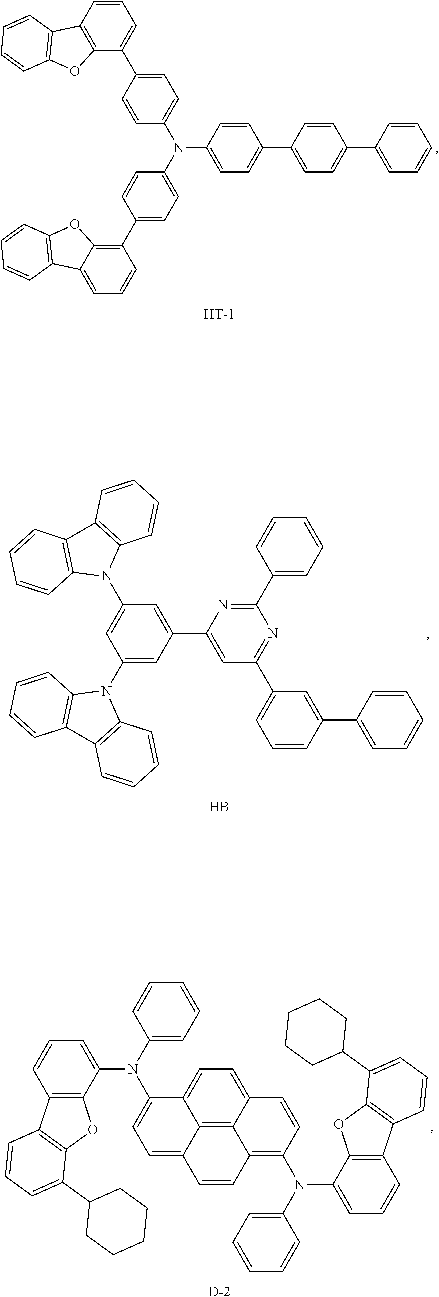

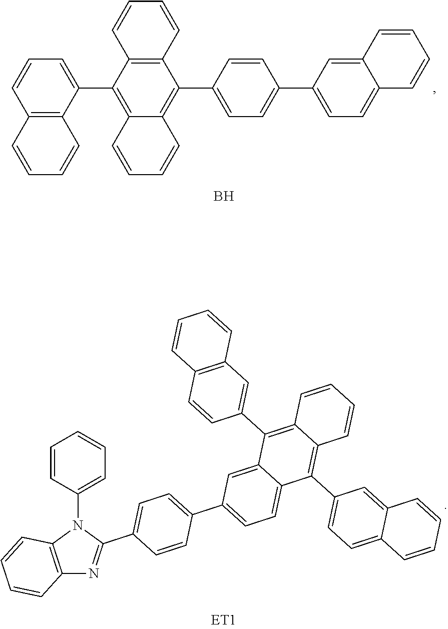

The device performance of Example 3-1 and Comparative Example 3-1 was measured. Color coordinates (CIE), voltages, and external quantum efficiency (EQE) were measured at a current density of 10 mA/cm², and a device lifetime (LT95) was a measured time taken for the device to decay to 97% of initial brightness at a constant current density of 80 mA/cm². These data are shown in Table 7.

TABLE 7
Device performance of Example 3-1 and Comparative Example 3-1

| | 10 mA/cm² | | | 80 mA/cm² |
|---|---|---|---|---|
| | CIE | Voltage | EQE | LT97 |
| Device No. | (x, y) | (V) | (%) | (h) |
| Example 3-1 | (0.137, 0.098) | 4.0 | 8.2 | 100 |
| Comparative | (0.137, 0.098) | 3.9 | 8.1 | 70 |
| Example 3-1 | | | | |

Example 3-1 and Comparative Example 3-1 were blue fluorescent devices, and the color coordinates of Example 3-1 and Comparative Example 3-1 shown in Table 7 were basically consistent. Example 3-1 used a device comprising the first organic layer and the second organic layer of the present application. It can be found from the comparison of device data that Example 3-1 and Comparative Example 3-1 had basically the same driving voltage and EQE, but Example 3-1 had a lifetime greatly improved by 43%. This indicates that the organic electroluminescent device comprising particular organic layer structures in the present application can improve the device lifetime and significantly improve the overall performance of the device.

As can be seen from the preceding data, the novel organic electroluminescent device disclosed in the present application and comprising a particular p-type dopant and particular organic layer structures can significantly improve the overall performance of both a single-layer device and a stacked device.

It is to be understood that various embodiments described herein are merely examples and not intended to limit the scope of the present disclosure. Therefore, it is apparent to the persons skilled in the art that the present disclosure as claimed may include variations of specific embodiments and preferred embodiments described herein. Many of materials and structures described herein may be substituted with other materials and structures without departing from the spirit of the present disclosure. It is to be understood that various theories as to why the present disclosure works are not intended to be limitative.

What is claimed is:

1. An organic electroluminescent device, comprising an anode, a cathode, and an organic layer disposed between the anode and the cathode; wherein
the organic layer comprises a first organic layer and a second organic layer;
the first organic layer comprises a first organic material and a first p-type dopant;
the second organic layer comprises a second organic material and a second p-type dopant;
the first organic layer is in contact with the second organic layer, and the second organic layer is above the first organic layer; and
the first p-type dopant and the second p-type dopant each independently have a structure represented by Formula 1: 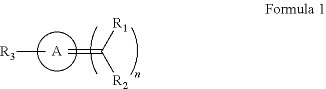
wherein
n is selected from an integer from 1 to 5;
the ring A is, at each occurrence identically or differently, selected from a conjugated ring having 4 to 30 ring atoms;
R₃ represents mono-substitution, multiple substitutions, or non-substitution;
R₁, R₂, and R₃ are, at each occurrence identically or differently, selected from hydrogen, deuterium, or a substituent;
at least one R₃ is selected from hydrogen, deuterium, or a substituent comprising at least two atoms; and
adjacent substituents R₁, R₂, R₃ can be optionally joined to form a ring.

2. The organic electroluminescent device according to claim 1, wherein a sum of a thickness of the first organic layer and a thickness of the second organic layer is less than or equal to 100 nm;
preferably, the sum of the thickness of the first organic layer and the thickness of the second organic layer is less than or equal to 50 nm;
more preferably, the sum of the thickness of the first organic layer and the thickness of the second organic layer is less than or equal to 20 nm.

3. The organic electroluminescent device according to claim 1, wherein the first organic material is the same as or different from the second organic material, and the first p-type dopant is the same as the second p-type dopant.

4. The organic electroluminescent device according to claim 1, wherein the first organic material is the same as or different from the second organic material, and the first p-type dopant is different from the second p-type dopant.

5. The organic electroluminescent device according to claim 1, wherein the first p-type dopant and/or the second p-type dopant have a lowest unoccupied molecular orbital (LUMO) of greater than or equal to −5.2 eV;
preferably, the first p-type dopant and/or the second p-type dopant have a LUMO of greater than or equal to −5.0 eV;
more preferably, the first p-type dopant and/or the second p-type dopant have a LUMO of greater than or equal to −4.9 eV.

6. The organic electroluminescent device according to claim 1, wherein a LUMO energy level of the first p-type dopant is less than or equal to a LUMO energy level of the second p-type dopant.

7. The organic electroluminescent device according to claim 1, wherein a LUMO energy level of the first p-type dopant is greater than or equal to a LUMO energy level of the second p-type dopant.

8. The organic electroluminescent device according to claim 1, wherein the first organic material and/or the second organic material have a highest occupied molecular orbital (HOMO) energy level of less than or equal to −4.5 eV;
preferably, the first organic material and/or the second organic material have a HOMO energy level of less than or equal to −4.8 eV.

9. The organic electroluminescent device according to claim 1, wherein the first organic material and/or the second organic material comprise a monotriarylamine structural unit or a bistriarylamine structural unit;
preferably, the first organic material and/or the second organic material comprise any one or more chemical structural units selected from the group consisting of: a monotriarylamine-carbazole structural unit, a monotriarylamine-thiophene structural unit, a monotriarylamine-furan structural unit, a monotriarylamine-fluorene structural unit, a bistriarylamine-carbazole structural unit, a bistriarylamine-thiophene structural unit, a bistriarylamine-furan structural unit, and a bistriarylamine-fluorene structural unit.

10. The organic electroluminescent device according to claim 1, wherein R₁ and/or R₂ are a substituent comprising at least one electron withdrawing group.

11. The organic electroluminescent device according to claim 1, wherein the first organic layer is in contact with the anode.

12. The organic electroluminescent device according to claim 1, further comprising a third organic layer above the second organic layer, wherein the third organic layer comprises a third organic material and a third p-type dopant;
the third organic material is the same as or different from the first organic material and/or the second organic material; and
the third p-type dopant is the same as or different from the first p-type dopant and/or the second p-type dopant.

13. The organic electroluminescent device according to claim 1, further comprising at least one emissive layer disposed between the second organic layer and the cathode.

14. The organic electroluminescent device according to claim 13, wherein the emissive layer comprises a emissive material, wherein the emissive material is a phosphorescent, fluorescent, or delayed fluorescence material.

15. The organic electroluminescent device according to claim 13, further comprising a fourth organic layer disposed between the second organic layer and the emissive layer, wherein the fourth organic layer comprises a fourth organic material;
preferably, the fourth organic material is the same as or different from the first organic material or the second organic material.

16. The organic electroluminescent device according to claim 13, further comprising a charge generation layer disposed between the emissive layer and the cathode, wherein the charge generation layer comprises a p-type charge generation layer.

17. The organic electroluminescent device according to claim 16, wherein the p-type charge generation layer of the charge generation layer comprises the first p-type dopant or the second p-type dopant.

18. The organic electroluminescent device according to claim 16, wherein the first organic layer or the second organic layer is in contact with the p-type charge generation layer of the charge generation layer.

19. An electronic assembly, comprising the organic electroluminescent device according to claim 1.
